(19) United States
(12) Patent Application Publication
(10) Pub. No.: US 2025/0313751 A1
(43) Pub. Date: Oct. 9, 2025

(54) MULTI-COMPONENT RARE-EARTH GARNET SCINTILLATORS

(71) Applicant: University of Tennessee Research Foundation, Knoxville, TN (US)

(72) Inventors: Mariya Zhuravleva, Knoxville, TN (US); Kaden Legrand Anderson, Knoxville, TN (US); Matheus Pianassola, Knoxville, TN (US); Charles L. Melcher, Oak Ridge, TN (US)

(73) Assignee: University of Tennessee Research Foundation, Knoxville, TN (US)

(21) Appl. No.: 18/866,904

(22) PCT Filed: May 19, 2023
(86) PCT No.: PCT/US2023/022910

§ 371 Date: Nov. 18, 2024

Related U.S. Application Data
(60) Provisional application No. 63/343,885, filed on May 19, 2022.

(51) Int. Cl. C09K 11/77; C30B 15/08; C30B 29/28; G01T 1/20

(52) U.S. Cl. CPC C09K 11/7774; C30B 15/08; C30B 29/28; G01T 1/2002; G01T 1/2018

(57) ABSTRACT

Multi-component rare-earth garnet optical materials comprising at least three different rare-earth elements and an optional activator ion are described. The optical materials include rare-earth garnet scintillators. Methods of preparing powders, ceramics, and single crystals of the optical materials are also described. In addition, radiation detectors comprising the rare-earth garnet scintillators are described.

### RELATED APPLICATIONS

This application claims priority to and the benefit of U.S. Provisional Patent Application Ser. No. 63/343,885, filed May 19, 2023; the disclosure of which is incorporated herein by reference in its entirety.

### PARTIES TO A JOINT RESEARCH AGREEMENT

The subject matter disclosed herein was made by, on behalf of, and/or in connection with one or more of the following parties to a joint research agreement: Siemens Medical Solutions USA, Inc., and The University of Tennessee. The agreement was in effect on and before the effective filing date of the presently disclosed subject matter, and the presently disclosed subject matter was made as a result of activities undertaken within the scope of the agreement.

### TECHNICAL FIELD

The presently disclosed subject matter relates to rare-earth garnet optical materials that comprise combinations of ions of at least three rare-earth elements. The presently disclosed subject matter further relates to scintillators of the optical materials, radiation detectors comprising the scintillator materials, to methods of using the scintillator materials to detect radiation, and to methods of making the optical materials.

### Abbreviations

%=percentage
° C.=degrees Celsius
Al=aluminum
at %=atomic percentage
a.u.=arbitrary unites
CCD=charge-coupled device
Ce=cerium
cm=centimeters
CT=computed tomography
DI=deionized
Dy=dysprosium
Em=emission
Er=erbium
Eu=europium
Exc=excitation
g=grams
Ga=gallium
Gd=gadolinium
h=hour
Ho=holium
keV=kiloelectron volts
kVA=kilovolt-amps
La=lanthanum
Lu=lutetium
LY=light yield
MeV=megaelectronvolt
min=minute
ml=milliliter
mm=millimeter
mol=mole
mPa=megapascal
Nd=neodymium
nm=nanometer
PEG=polyethylene glycol
PET=positron emission tomography
ph=photons
PL=photoluminescence
Pm=promethium
PMT=photomultiplier tube
Pr=praseodymium
PTFE=polytetrafluoroethylene
PVA=polyvinyl alcohol
RE=rare-earth
RF=radiofrequency
RL=radioluminescence
Sc=scandium
Sm=samarium
Tb=terbium
Tm=thulium
XRD=x-ray diffraction
Y=yttrium
Yb=ytterbium

### BACKGROUND

Optical materials include phosphors and scintillators, which can emit light pulses in response to impinging radiation, such as X-rays, gamma rays, and neutrons. Inorganic scintillators are widely used in radiation detectors that have a wide range of applications in medical imaging, particle physics, geological exploration, homeland security, and other related areas due to their high density and high atomic number compared to gas detectors and organic scintillators. These various applications use scintillators that have suitable luminescent properties when used in different areas. Considerations in selecting scintillator and other optical materials typically include, but are not limited to, luminosity, decay time, and emission wavelength.

While a variety of optical materials have been developed, there is an ongoing need to develop additional optical materials with improved properties for particular applications.

### SUMMARY

This summary lists several embodiments of the presently disclosed subject matter, and in many cases lists variations and permutations of these embodiments. This summary is merely exemplary of the numerous and varied embodiments. Mention of one or more representative features of a given embodiment is likewise exemplary. Such an embodiment can typically exist with or without the feature(s) mentioned; likewise, those features can be applied to other embodiments of the presently disclosed subject matter, whether listed in this summary or not. To avoid excessive repetition, this Summary does not list or suggest all possible combinations of such features.

In some embodiments, the presently disclosed subject matter provides an optical material comprising a composition of the formula:

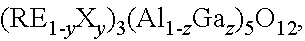

wherein: 0≤y≤0.1; 0≤z≤1; RE is a combination of ions of three or more rare-earth elements selected from the group comprising Y, Sc, Lu, Yb, Tm, Er, Ho, Dy, Tb, Gd, Eu, Sm, Nd, Pr, and La; and X is one or more activator ions selected from the group comprising a Ce ion, a Tb ion, a Dy ion, a Eu ion, an Yb ion, and a Pr ion. In some embodiments, z is 0.

In some embodiments, RE is a combination of ions of three, four, five or six elements selected from the group comprising Y, Sc, Lu, Yb, Tm, Er, Ho, Dy, Tb, Gd, Eu, Sm, Nd, Pr, and La. In some embodiments, RE is a combination of ions of at least three elements selected from the group comprising Y, Lu, Tb, and Gd.

In some embodiments, y is 0. In some embodiments, 0.001≤y≤0.1. In some embodiments, 0.005≤y≤0.05; optionally wherein y is 0.005, 0.02, or 0.05. In some embodiments, X is a Ce ion, a Pr ion, or a mixture thereof, optionally wherein X is Ce³⁺.

In some embodiments, the optical material comprises a composition selected from the group comprising:
(Y_{0.2}Gd_{0.2}Tb_{0.2}Y_{0.2}Lu_{0.2})₃Al₅O₁₂;
(Y_{0.25}Gd_{0.25}Er_{0.25}Lu_{0.25})₃Al₅O₁₂;
(Y_{0.25}Gd_{0.25}Ho_{0.25}Lu_{0.25})₃Al₅O₁₂;
(Y_{0.2}Gd_{0.2}Dy_{0.2}Lu_{0.2})₃Al₅O₁₂;
(Y_{0.25}Gd_{0.25}Tb_{0.25}Lu_{0.25})₃Al₅O₁₂;
(Y_{0.2}Eu_{0.2}Gd_{0.2}Yb_{0.2}Lu_{0.2})₃Al₅O₁₂;
(Y_{0.1667}Eu_{0.1667}Gd_{0.1667}Tb_{0.1667}Yb_{0.1667}Lu_{0.1667})₃Al₅O₁₂;
(Y_{0.25}Gd_{0.25}Tb_{0.25}Lu_{0.25})₃Al₅O₁₂;
(Y_{0.25}Nd_{0.25}Gd_{0.25}Lu_{0.25})₃Al₅O₁₂;
(Y_{0.25}Pr_{0.25}Gd_{0.25}Lu_{0.25})₃Al₅O₁₂; and
(Y_{0.25}La_{0.25}Gd_{0.25}Lu_{0.25})₃Al₅O₁₂.

In some embodiments, the optical material comprises a composition selected from the group comprising:
(Y_{0.199}Gd_{0.199}Tb_{0.199}Yb_{0.199}Lu_{0.199}Ce_{0.005})₃Al₅O₁₂;
(Y_{0.24875}Gd_{0.24875}Er_{0.24875}Lu_{0.24875}Ce_{0.005})₃Al₅O₁₂;
(Y_{0.24875}Gd_{0.24875}Ho_{0.24875}Lu_{0.24875}Ce_{0.005})₃Al₅O₁₂;
(Y_{0.199}Gd_{0.199}Tb_{0.199}Dy_{0.199}Lu_{0.199}Ce_{0.005})₃Al₅O₁₂;
(Y_{0.24875}Gd_{0.24875}Tb_{0.24875}Lu_{0.24875}Ce_{0.005})₃Al₅O₁₂;
(Y_{0.199}Eu_{0.199}Gd_{0.199}Yb_{0.199}Lu_{0.199}Ce_{0.005})₃Al₅O₁₂;
(Y_{0.16583}Eu_{0.16583}Gd_{0.16583}Yb_{0.16583}Lu_{0.16583}Ce_{0.005})₃Al₅O₁₂;
(Y_{0.24875}Sm_{0.24875}Gd_{0.24875}Lu_{0.24875}Ce_{0.005})₃Al₅O₁₂;
(Y_{0.24875}Nd_{0.24875}Gd_{0.24875}Lu_{0.24875}Ce_{0.005})₃Al₅O₁₂;
(Y_{0.24875}Pr_{0.24875}Gd_{0.24875}Lu_{0.24875}Ce_{0.005})₃Al₅O₁₂;
(Y_{0.24875}La_{0.24875}Gd_{0.24875}Lu_{0.24875}Ce_{0.005})₃Al₅O₁₂;
(Y_{0.245}Gd_{0.245}Tb_{0.245}Lu_{0.245}Ce_{0.002})₃Al₅O₁₂;
(Y_{0.2375}Gd_{0.2375}Tb_{0.2375}Lu_{0.2375}Ce_{0.005})₃Al₅O₁₂;
(Y_{0.2375}Gd_{0.2375}Tb_{0.2375}Lu_{0.24875}Ce_{0.005})₃Al₅O₁₂; and
(Y_{0.294}Gd_{0.294}Tb_{0.098}LU_{0.294}Ce_{0.02})₃Al₅O₁₂.

In some embodiments, the optical material comprises a composition selected from the group comprising:
(Y_{0.33167}Tb_{0.33167}Gd_{0.33167}Ce_{0.005})₃Al₅O₁₂;
(Lu_{0.33167}Y_{0.33167}Gd_{0.33167}Ce_{0.005})₃Al₅O₁₂;
(Lu_{0.33167}Y_{0.33167}Tb_{0.33167}Ce_{0.005})₃Al₅O₁₂;
(Lu_{0.24875}Y_{0.24875}Tb_{0.24875}Gd_{0.24875}Ce_{0.005})₃Al₅O₁₂; and
(Lu_{0.245}Y_{0.245}Tb_{0.245}Gd_{0.245}Ce_{0.02})₃Al₅O₁₂.

In some embodiments, the optical material provides light emission from an optically active RE ion upon stimulation of the optical material with high energy radiation, optionally wherein said optically active RE ion is a Tb ion.

In some embodiments, the presently disclosed subject matter provides a radiation detector comprising an optical material of the presently disclosed subject matter and a photon detector, optionally wherein the optical material comprises a composition selected from the group comprising:
(Y_{0.33167}Tb_{0.33167}Gd_{0.33167}Ce_{0.005})₃Al₅O₁₂;
(Lu_{0.33167}Yo_{0.33167}Gd_{0.33167}Ce_{0.005})₃Al₅O₁₂;
(Lu_{0.33167}Yo_{0.33167}Tb_{0.33167}Ce_{0.005})₃Al₅O₁₂;
(Lu_{0.24875}Y_{0.24875}Tb_{0.24875}Gd_{0.24875}Ce_{0.005})₃Al₅O₁₂; and
(Lu_{0.245}Y_{0.245}Tb_{0.245}Gd_{0.245}Ce_{0.02})₃Al₅O₁₂.

In some embodiments, the presently disclosed subject matter provides a method of detecting gamma rays, X-rays, cosmic rays, and/or particles having an energy of 1 keV or greater, the method comprising using the radiation detector. In some embodiments, the presently disclosed subject matter provides for the use of the radiation detector in medical imaging, homeland security, or high energy physics research.

In some embodiments, the presently disclosed subject matter provides a method of preparing an optical material of the presently disclosed subject matter, wherein the method comprises preparing a single crystal of the optical material from a melt.

In some embodiments, the presently disclosed subject matter provides a method of preparing an optical material of the presently disclosed subject matter, wherein the method comprises preparing a powder of the optical material by: (i) preparing a foam by heating an aqueous solution comprising a polymer, optionally polyvinyl alcohol (PVA) or polyethylene glycol (PEG), and a mixture of metal nitrates, wherein the metal nitrates comprise ions of elements that correspond to elements of the optical material, and crushing said foam to provide the powder; or (ii) coprecipitating powder by adding an aqueous solution comprising a mixture of metal nitrates and ammonium sulfate to an aqueous solution of ammonium carbonate, wherein the metal nitrates comprise ions of elements that correspond to elements of the optical material.

In some embodiments, the presently disclosed subject matter provides a method of preparing an optical material of the presently disclosed subject matter wherein the method comprises preparing a ceramic of the optical material by a technique selected from

It is an object of the presently disclosed subject matter to provide multi-component rare-earth garnet optical materials, e.g. scintillators, radiation detectors comprising the optical materials, methods of using the radiation detectors, and methods of preparing the optical materials.

An object of the presently disclosed subject matter having been stated hereinabove, and which is achieved in whole or in part by the presently disclosed subject matter, other objects will become evident upon a review of the description and as the description proceeds when taken in connection with the accompanying drawings and examples as best described herein below.

### BRIEF DESCRIPTION OF THE DRAWINGS

FIG. 1 is a composite photographic image of crystals of exemplary rare-earth garnet compositions of the presently disclosed subject matter: (1) (Lu_{1/3}Y_{1/3}Gd_{1/3})₃Al₅O₁₂:Ce 0.5%, (2) (Lu_{1/3}Y_{1/3}Tb_{1/3})₃Al₅O₁₂:Ce 0.5%, (3) (Y_{1/3}Tb_{1/3}Gd_{1/3})₃Al₅O₁₂:Ce 0.5%, (4) (Lu_{1/4}Y_{1/4}Tb_{1/4}Gd_{1/4})₃Al₅O₁₂:Ce 0.5%, (5) (Lu_{1/4}Y_{1/4}Tb_{1/4}Gd_{1/4})₃Al₅O₁₂:Ce 2%, and (6) (Lu_{1/5}Y_{1/5}Dy_{1/5}Tb_{1/5}Gd_{1/5})₃Al₅O₁₂:Ce 0.5%. All crystals were clear and yellow in color. The scale bar in the upper left corner represents 1 centimeter (cm).

FIG. 2 is a composite photographic image of green body pellets (1-6) and a hot-pressed pellet (7) of ceramics of exemplary rare-earth garnet compositions of the presently disclosed subject matter. The numbers in the image correspond to the following compositions (1) (Y_{1/4}Sm_{1/4}Gd_{1/4}Lu_{1/4})₃Al₅O₁₂:Ce 0.5%; (2) (Y_{1/4}Nd_{1/4}Gd_{1/4}Lu_{1/4})₃Al₅O₁₂:Ce 0.5%; (3) (Y_{1/4}Pr_{1/4}Gd_{1/4}Lu_{1/4})₃Al₅O₁₂:Ce 0.5%; (4) (Y_{1/4}Sm_{1/4}Gd_{1/4}Lu_{1/4})₃Al₅O₁₂; (5) (Y_{1/4}Nd_{1/4}Gd_{1/4}Lu_{1/4})₃Al₅O₁₂; (6) (Y_{1/4}Pr_{1/4}Gd_{1/4}Lu_{1/4})₃Al₅O₁₂; and (7) (Y_{1/4}Gd_{1/4}Tb_{1/4}Lu_{1/4})₃Al₅O₁₂:Ce 2%.

FIG. 3 is a graph showing the room temperature x-ray diffraction (XRD) patterns (intensity expressed in arbitrary unites (a.u.) versus 2 theta (2θ) angle expressed in degrees (°)) of multicomponent (RE₁₋ₓCeₓ)₃Al₅O₁₂ compositions of the presently disclosed subject matter. From top to bottom, the XRD patterns were for: (Lu_{1/6}Y_{1/6}Ho_{1/6}Dy_{1/6}Tb_{1/6}Gd_{1/6})₃Al₅O₁₂:Ce; (Lu_{1/5}Y_{1/5}Dy_{1/5}Tb_{1/5}Gd_{1/5})₃Al₅O₁₂:Ce; (Lu_{1/4}Y_{1/4}Dy_{1/4}Gd_{1/4})₃Al₅O₁₂:Ce; and (Lu_{1/3}Y_{1/3}Gd_{1/3})₃Al₅O₁₂:Ce. The pattern of Lu₃Al₅O₁₂ (see reference [1]) is plotted for comparison.

FIG. 4A is a graph showing the emission (Em) and excitation (Exc) spectra (intensity expressed in arbitrary unites (a.u.) versus wavelength expressed in nanometers (nm)) of an exemplary rare-earth garnet of the presently disclosed subject matter: (Lu_{1/3}Y_{1/3}Gd_{1/3})₃Al₅O₁₂:Ce 0.5%. The dashed line is the Exc spectrum at 545 nm Em. The lighter solid line is the Em spectrum at 448 nm Exc and the darker solid line is the Em spectrum at 341 nm Exc.

FIG. 4B is a graph showing the emission (Em) and excitation (Exc) spectra (intensity expressed in arbitrary unites (a.u.) versus wavelength expressed in nanometers (nm)) of an exemplary rare-earth garnet of the presently disclosed subject matter: (Y_{1/3}Tb_{1/3}Gd_{1/3})₃Al₅O₁₂:Ce 0.5%. The dashed line is the Exc spectrum at 545 nm Em. The lighter solid line is the Em spectrum at 457 nm Exc and the darker solid line is the Em spectrum at 322 nm Exc.

FIG. 4C is a graph showing the emission (Em) and excitation (Exc) spectra (intensity expressed in arbitrary unites (a.u.) versus wavelength expressed in nanometers (nm)) of an exemplary rare-earth garnet of the presently disclosed subject matter: (Lu_{1/3}Y_{1/3}Tb_{1/3})₃Al₅O₁₂:Ce 0.5%. The dashed line is the Exc spectrum at 542 nm Em. The lighter solid line is the Em spectrum at 448 nm Exc and the darker solid line is the Em spectrum at 320 nm Exc.

FIG. 4D is a graph showing the emission (Em) and excitation (Exc) spectra (intensity expressed in arbitrary unites (a.u.) versus wavelength expressed in nanometers (nm)) of an exemplary rare-earth garnet of the presently disclosed subject matter: (Lu_{1/4}Y_{1/4}Tb_{1/4}Gd_{1/4})₃Al₅O₁₂:Ce 0.5%. The dashed line is the Exc spectrum at 552 nm Em. The lighter solid line is the Em spectrum at 456 nm Exc and the darker solid line is the Em spectrum at 335 nm Exc.

FIG. 4E is a graph showing the emission (Em) and excitation (Exc) spectra (intensity expressed in arbitrary unites (a.u.) versus wavelength expressed in nanometers (nm)) of an exemplary rare-earth garnet of the presently disclosed subject matter: (Lu_{1/5}Y_{1/5}Dy_{1/5}Tb_{1/5}Gd_{1/5})₃Al₅O₁₂:Ce 0.5%. The dashed line is the Exc spectrum at 542 nm Em. The lighter solid line is the Em spectrum at 453 nm Exc and the darker solid line is the Em spectrum at 338 nm Exc.

FIG. 5A is a graph showing the X-ray excited luminescence spectrum (intensity expressed in arbitrary unites (a.u.) versus wavelength expressed in nanometers (nm)) of an exemplary rare-earth garnet crystal composition of the presently disclosed subject matter: (Y_{1/3}Tb_{1/3}Gd_{1/3})₃Al₅O₁₂:Ce 0.5%.

FIG. 5B is a graph showing the X-ray excited luminescence spectrum (intensity expressed in arbitrary unites (a.u.) versus wavelength expressed in nanometers (nm)) of an exemplary rare-earth garnet crystal composition of the presently disclosed subject matter: (Lu_{1/3}Y_{1/3}Gd_{1/3})₃Al₅O₁₂:Ce 0.5%.

FIG. 5C is a graph showing the X-ray excited luminescence spectrum (intensity expressed in arbitrary unites (a.u.) versus wavelength expressed in nanometers (nm)) of an exemplary rare-earth garnet crystal composition of the presently disclosed subject matter: (Lu_{1/3}Y_{1/3}Tb_{1/3})₃Al₅O₁₂:Ce 0.5%.

FIG. 5D is a graph showing the X-ray excited luminescence spectra (intensity expressed in arbitrary unites (a.u.) versus wavelength expressed in nanometers (nm)) of crystals of exemplary rare-earth garnet compositions of the presently disclosed subject matter: (Lu_{1/4}Y_{1/4}Tb_{1/4}Gd_{1/4})₃Al₅O₁₂:Ce 0.5% (darker solid line) or 2% (lighter solid line).

FIG. 5E is a graph showing the X-ray excited luminescence spectra (intensity expressed in arbitrary unites (a.u.) versus wavelength expressed in nanometers (nm)) of crystals of two exemplary rare-earth garnet compositions of the presently disclosed subject matter: (Lu_{1/5}Y_{1/5}Dy_{1/5}Tb_{1/5}Gd_{1/5})₃Al₅O₁₂:Ce 0.5% (darker solid line) or 1% (lighter solid line).

FIG. 5F is a graph showing X-ray excited luminescence spectra (intensity expressed in arbitrary unites (a.u.) versus wavelength expressed in nanometers (nm)) of pellets of three exemplary rare-earth garnet compositions of the presently disclosed subject matter (Lu_{1/3}Y_{1/3}Gd_{1/3})₃Al₅O₁₂:Ce (darker solid line), (Lu_{1/4}Y_{1/4}Gd_{1/4}La_{1/4})₃Al₅O₁₂:Ce (dashed line), and (Lu_{1/3}Y_{1/3}Gd_{1/3})₃(Al_{1/3}Ga_{1/3}Sc_{1/3})₅O₁₂:Ce (lighter solid line), all with Ce at 1%.

FIG. 6 is a graph of the pulse height spectra (counts versus channel number) of multicomponent (RE₁₋ₓCeₓ)₃Al₅O₁₂ crystals excited at 662 keV (¹³⁷Cs). The spectrum shown as a light grey solid line is for (Y_{1/3}Tb_{1/3}Gd_{1/3})₃Al₅O₁₂:Ce 0.5%; the spectrum shown as a black solid line is for (Lu_{1/3}Y_{1/3}Gd_{1/3})₃Al₅O₁₂:Ce 0.5%; the spectrum shown as a black dotted line is for (Lu_{1/3}Y_{1/3}Tb_{1/3})₃Al₅O₁₂:Ce 0.5%; the spectrum shown as a medium grey solid line is for (Lu_{1/4}Y_{1/4}Tb_{1/4}Gd_{1/4})₃Al₅O₁₂:Ce 0.5%; and the spectrum shown as the medium grey dotted line is for (Lu_{1/4}Y_{1/4}Tb_{1/4}Gd_{1/4})₃Al₅O₁₂:Ce 2%.

FIG. 7A is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.2}Gd_{0.2}Tb_{0.2}Yb_{0.2}Lu_{0.2})₃Al₅O₁₂.

FIG. 7B is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.199}Gd_{0.199}Tb_{0.199}Yb_{0.199}Lu_{0.199}Ce_{0.005})₃Al₅O₁₂.

FIG. 7C is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.25}Gd_{0.25}Er_{0.25}Lu_{0.25})₃Al₅O₁₂.

FIG. 7D is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.24875}Gd_{0.24875}Er_{0.24875}Lu_{0.24875}Ce_{0.005})₃Al₅O₁₂.

FIG. 7E is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.25}Gd_{0.25}Ho_{0.25}Lu_{0.25})₃Al₅O₁₂.

FIG. 7F is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.24875}Gd_{0.24875}Ho_{0.24875}Lu_{0.24875}Ce_{0.005})₃Al₅O₁₂.

FIG. 7G is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.2}Gd_{0.2}Tb_{0.2}Dy_{0.2}Lu_{0.2})₃Al₅O₁₂.

FIG. 7H is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.199}Gd_{0.199}Tb_{0.199}Dy_{0.199}Lu_{0.199}Ce_{0.005})₃Al₅O₁₂.

FIG. 7I is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.25}Gd_{0.25}Tb_{0.25}Lu_{0.25})₃Al₅O₁₂.

FIG. 7J is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.24875}Gd_{0.24875}Tb_{0.24875}Lu_{0.24875}Ce_{0.005})₃Al₅O₁₂.

FIG. 7K is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.2}Eu_{0.2}Gd_{0.2}Yb_{0.2}Lu_{0.2})₃Al₅O₁₂.

FIG. 7L is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.199}Eu_{0.199}Gd_{0.199}Yb_{0.199}Lu_{0.199}Ce_{0.005})₃Al₅O₁₂.

FIG. 7M is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.1667}Eu_{0.1667}Gd_{0.1667}Tb_{0.1667}Yb_{0.1667}Lu_{0.1667})₃Al₅O₁₂.

FIG. 7N is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.16583}Eu_{0.16583}Gd_{0.16583}Tb_{0.16583}Yb_{0.16583}Lu_{0.16583}Ce_{0.005})₃Al₅O₁₂.

FIG. 7O is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.25}Sm_{0.25}Gd_{0.25}Lu_{0.25})₃Al₅O₁₂.

FIG. 7P is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.24875}Sm_{0.24875}Gd_{0.24875}Lu_{0.24875}Ce_{0.005})₃Al₅O₁₂.

FIG. 7Q is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.25}Nd_{0.25}Gd_{0.25}Lu_{0.25})₃Al₅O₁₂.

FIG. 7R is a graph showing the radioluminescence (RL) plot (intensity measured in arbitrary units (a.u.) versus wavelength measured in nanometers (nm) for a rare-earth garnet composition of the presently disclosed subject matter having (Y_{0.24875}Nd_{0.24875}Gd_{0.24875}Lu_{0.24875}Ce_{0.005})₃Al₅O₁₂.

FIG. 7S is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.25}Pr_{0.25}Gd_{0.25}Lu_{0.25})₃Al₅O₁₂.

FIG. 7T is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.24875}Pr_{0.24875}Gd_{0.24875}Lu_{0.24875}Ce_{0.005})₃Al₅O₁₂.

FIG. 7U is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.25}La_{0.25}Gd_{0.25}Lu_{0.25})₃Al₅O₁₂.

FIG. 7V is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.24875}La_{0.24875}Gd_{0.24875}Lu_{0.24875}Ce_{0.005})₃Al₅O₁₂.

FIG. 7W is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.245}Gd_{0.245}Tb_{0.245}Lu_{0.245}Ce_{0.02})₃Al₅O₁₂.

FIG. 7X is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.2375}Gd_{0.2375}Tb_{0.2375}Lu_{0.2375}Ce_{0.05})₃Al₅O₁₂.

FIG. 7Y is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.163}Gd_{0.163}Tb_{0.49}Lu_{0.163}Ce_{0.02})₃Al₅O₁₂.

FIG. 7Z is a graph showing the radioluminescence (RL) plot (intensity measured in arbitrary units (a.u.) versus wavelength measured in nanometers (nm) for a rare-earth garnet composition of the presently disclosed subject matter having the formula (Y_{0.294}Gd_{0.294}Tb_{0.098}Lu_{0.294}Ce_{0.02})₃Al₅O₁₂.

FIG. 8 is a schematic drawing of an apparatus for detecting radiation according to the presently disclosed subject matter. Apparatus 10 includes photon detector 12 optically coupled to scintillator material 14. Apparatus 10 can optionally include electronics 16 for recording and/or displaying electronic signal from photon detector 12. Thus, optional electronics 16 can be in electronic communication with photon detector 12.

### DETAILED DESCRIPTION

The presently disclosed subject matter will now be described more fully. The presently disclosed subject matter can, however, be embodied in different forms and should not be construed as limited to the embodiments set forth herein below and in the accompanying Examples. Rather, these embodiments are provided so that this disclosure will be thorough and complete, and will fully convey the scope of the embodiments to those skilled in the art.

All references listed herein, including but not limited to all patents, patent applications and publications thereof, and scientific journal articles, are incorporated herein by reference in their entireties to the extent that they supplement, explain, provide a background for, or teach methodology, techniques, and/or compositions employed herein.

### I. Definitions

While the following terms are believed to be well understood by one of ordinary skill in the art, the following definitions are set forth to facilitate explanation of the presently disclosed subject matter.

Unless defined otherwise, all technical and scientific terms used herein have the same meaning as commonly understood to one of ordinary skill in the art to which the presently disclosed subject matter belongs.

Following long-standing patent law convention, the terms “a”, “an”, and “the” refer to “one or more” when used in this application, including the claims.

The term “and/or” when used in describing two or more items or conditions, refers to situations where all named items or conditions are present or applicable, or to situations wherein only one (or less than all) of the items or conditions is present or applicable.

The use of the term “or” in the claims is used to mean “and/or” unless explicitly indicated to refer to alternatives only or the alternatives are mutually exclusive, although the disclosure supports a definition that refers to only alternatives and “and/or.” As used herein “another” can mean at least a second or more.

The term “comprising”, which is synonymous with “including,” “containing,” or “characterized by” is inclusive or open-ended and does not exclude additional, unrecited elements or method steps. “Comprising” is a term of art used in claim language which means that the named elements are essential, but other elements can be added and still form a construct within the scope of the claim.

As used herein, the phrase “consisting of” excludes any element, step, or ingredient not specified in the claim. When the phrase “consists of” appears in a clause of the body of a claim, rather than immediately following the preamble, it limits only the element set forth in that clause, other elements are not excluded from the claim as a whole.

As used herein, the phrase “consisting essentially of” limits the scope of a claim to the specified materials or steps, plus those that do not materially affect the basic and novel characteristic(s) of the claimed subject matter.

With respect to the terms “comprising”, “consisting of”, and “consisting essentially of”, where one of these three terms is used herein, the presently disclosed and claimed subject matter can include the use of either of the other two terms.

Unless otherwise indicated, all numbers expressing quantities of time, temperature, light output, atomic (at) or mole (mol) percentage (%), and so forth used in the specification and claims are to be understood as being modified in all instances by the term “about”. Accordingly, unless indicated to the contrary, the numerical parameters set forth in this specification and attached claims are approximations that can vary depending upon the desired properties sought to be obtained by the presently disclosed subject matter.

As used herein, the term “about”, when referring to a value is meant to encompass variations of in one example ±20% or ±10%, in another example ±5%, in another example ±1%, and in still another example ±0.1% from the specified amount, as such variations are appropriate to perform the disclosed methods.

The term “scintillator” refers to a material that emits light (e.g., visible light) in response to stimulation by high energy radiation (e.g., X, α, β, or γ radiation).

The term “phosphor” as used herein refers to a material that emits light (e.g., visible light) in response to irradiation with electromagnetic or particle radiation. Thus, phosphors are materials that can emit light (e.g., of a particular wavelength or wavelength range) upon exposure to ultraviolet or visible light (e.g., of a particular wavelength or wavelength range).

In some embodiments, the compositional formula expression of an optical material (e.g., a scintillation material or a phosphor) can contain a colon or comma, wherein the composition of the main or base matrix material (e.g., the main rare earth garnet matrix, i.e., RE₃Al₅O₁₂) is indicated on the left side of the colon or comma, and an activator (or dopant ion) is indicated on the right side of the colon or comma. Alternatively, compositional formula expression can be free of a colon and the activator (or dopant), if present, can be included with the elements that it replaces, e.g., (RE/activator)₃Al₅O₁₂.

The term “high energy radiation” can refer to electromagnetic radiation having energy higher than that of ultraviolet radiation, including, but not limited to X radiation (i.e., X-ray radiation), alpha (a) particles, gamma (γ) radiation, and beta (p) radiation. In some embodiments, the high energy radiation refers to gamma rays, cosmic rays, X-rays, and/or particles having an energy of 1 keV or greater. Scintillator materials as described herein can be used as components of radiation detectors in apparatuses such as counters, image intensifiers, and computed tomography (CT) scanners.

“Optical coupling” as used herein refers to a physical coupling between a scintillator and a photosensor, e.g., via the presence of optical grease or another optical coupling compound (or index matching compound) that bridges the gap between the scintillator and the photosensor. In addition to optical grease, optical coupling compounds can include, for example, liquids, oils and gels.

“Light output” can refer to the number of light photons produced per unit energy deposited, e.g., by a gamma ray being absorbed, typically the number of light photons/MeV.

As used herein, chemical ions can be represented simply by their chemical element symbols alone (e.g., Eu for europium ion(s) (e.g., Eu²⁺) or Sm for samarium ion(s) (e.g., Sm²⁺)).

The term “rare earth element” as used herein refers to one or more elements selected from a lanthanide (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho) erbium (Er), thulium (Tm), ytterbium (Yb) and lutetium (Lu)), scandium (Sc), and yttrium (Y).

The term “transition metal element” as used herein refers to one or more elements selected from titanium (Ti), vanadium (V), chromium (Cr), manganese (Mn), iron (Fe), cobalt (Co), nickel (Ni), copper (Cu), zinc (Zn), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), rutherfordium (Rf), dubnium (Db), seborgium (Sg), bohrium (Bh), hassium (Hs), meitnerium (Mt), darmstadtium (Ds), roentgenium (Rg), and copernicium (Cn).

### II. Multi-Component Rare-Earth Garnet Materials and Related Devices and Methods

The presently disclosed subject matter provides multi-component rare-earth garnet optical materials. These optical materials can be phosphors and/or scintillators. In some embodiments, the optical materials comprise or consist of compositions of the general formula (RE_{1-y}X_{y})₃(Al_{1-z}Ga_{z})₅O₁₂, where RE represents ions of a combination of three or more rare-earth elements (including Y and Sc). The rare earth elements can thus be selected from the group including Y, Sc, Lu, Yb, Tm, Er, Ho, Dy, Tb, Gd, Eu, Sm, Nd, Pr, and La. X represents a luminescent activator, e.g., a Ce ion, a Tb ion, a Dy ion, a Eu ion, a Yb ion, or a Pr ion, while y is the relative activator concentration, and is in the range of 0≤y≤0.1. Thus, between 0% and 10% of the total amount of rare-earth element ions (RE) can be replaced by one or more activator ions. Although small amounts of X ions (e.g., Ce, Tb, Dy, Eu, Yb, or Pr ions) can act as a luminescent activator, optically active matrix elements, e.g., Yb, Er, Ho, Dy, Tb, Gd, Eu, Sm, Nd, and Pr, which are typically present in larger amounts than the activator, can also contribute to luminescence. The relative concentration of Ga compared to Al in the garnet matrix, represented by variable z, is in the range 0≤z≤1. In addition, in some embodiments, some of the Al or Ga content can be replaced by a rare-earth element ion, e.g., a Sc ion.

The concentrations of rare-earth elements in the optical material main matrix (i.e., i.e., (RE)₃(Al_{1-z}Ga_{z})₅O₁₂, an optical material without an activator or codopant ion) can be either equimolar or non-equimolar in the melt or alternatively in the finished crystal or ceramic. In the case of a stoichiometric congruently melting compound, in some embodiments, the concentrations of rare-earth elements are equimolar. For example, in a material with ions of four different rare-earth elements, each ion can comprise one fourth (i.e., 25%) of the total amount of RE ions. An exemplary formula with equimolar RE is, for instance, (Lu_{1/4}Y_{1/4}Tb_{1/4}Gd_{1/4})₃Al₅O₁₂ (which can also be represented as (Lu_{0.25}Y_{0.25}Tb_{0.25}Gd_{0.25})₃Al₅O₁₂, i.e., when the relative amount of particular RE ions in the formula is represented as a percentage rather than as a ratio).

In the case of an incongruently melting compound, in some embodiments, the concentrations of rare-earth elements can vary from equimolar as needed to obtain congruency. An exemplary formula where the rare-earth elements are not equimolar is, for example (Y_{3/8}Dy_{1/8}Tb_{1/4}Gd_{1/4})₃Al₅O₁₂ (which can also be represented as (Y_{0.375}Dy_{0.125}Tb_{0.25}Gd_{0.25})₃Al₅O₁₂). In some embodiments, the amount of activator ion X (relative to the total amount of RE ions), if present, such as Ce or Pr, is provided as a percentage (i.e., an atomic percentage) after the colon in an optical material formula (i.e., (RE)₃(Al_{1-z}Ga_{z})₅O₁₂:X y %), as an alternative representation format to the general formula described above, i.e., (RE_{1-y}X_{y})₃(Al_{1-z}Ga_{z})₅O₁₂, where the relative amount of activator ion, X, is included as a ratio or percentage inside the parentheses also describing the combination of rare-earth element ions RE.

In the case of a wide variation in rare-earth element ionic radius, concentrations of rare-earth elements of different ionic radii can be adjusted to stabilize the cubic garnet phase or achieve congruent melting, taking into account the segregation at the solid-liquid interface. Examples of these include, but are not limited to, (Lu_{1/4}Y_{1/4}Tb_{1/4}Gd_{1/4})₃(Al_{1/2}Ga_{1/2})₅O₁₂:Ce, (Y_{3/8}Dy_{1/8}Tb_{1/4}Gd_{1/4})₃Al₅O₁₂:Ce, and (Lu_{1/9}Y_{1/9}Tb_{2/9}Gd_{2/9}Sm_{3/9})₃Al₅O₁₂:Ce.

In some embodiments, e.g., when doped with an activator such as trivalent Ce or Pr, the presently disclosed optical materials become scintillators suitable for radiation detection applications including medical imaging, homeland security, and high energy physics experiments.

Accordingly, in some embodiments, the presently disclosed subject matter provides an optical material comprising or consisting of a composition of the formula:

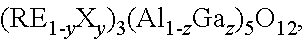

wherein: 0≤y≤0.1; 0≤z≤1; RE is a combination of ions of three or more rare-earth elements selected from the group comprising Y, Sc, Lu, Yb, Tm, Er, Ho, Dy, Tb, Gd, Eu, Sm, Nd, Pr, and La; and X is one or more activator ions selected from the group comprising a Ce ion, a Tb ion, a Dy ion, a Eu ion, a Yb ion, and a Pr ion. As noted above, the relative concentrations of each of the rare-earth element ions in the optical material can be about the same (i.e., equimolar) or can be different.

In some embodiments, z is 0. Thus, in some embodiments, the optical material does not include any Ga and the optical material comprises or consists of the formula (RE_{1-y}X_{y})₃Al₅O₁₂.

In some embodiments, RE is a combination of ions of three, four, five or six elements selected from the group comprising Y, Sc, Lu, Yb, Tm, Er, Ho, Dy, Tb, Gd, Eu, Sm, Nd, Pr, and La. In some embodiments, RE is a combination of ions of at least three elements selected from Y, Lu, Tb, and Gd. In some embodiments, RE comprises a Y ion. In some embodiments, RE comprises a Lu ion.

In some embodiments, y is 0 (and the optical material does not include an activator ion X). For example, in some embodiments, the optical material comprises or consists of a composition selected from the group comprising:
(Y_{0.2}Gd_{0.2}Tb_{0.2}Y_{0.2}Lu_{0.2})₃Al₅O₁₂; (Y_{0.25}Gd_{0.25}Er_{0.25}Lu_{0.25})₃Al₅O₁₂;
(Y_{0.25}Gd_{0.25}Ho_{0.25}Lu_{0.25})₃Al₅O₁₂; (Y_{0.2}Gd_{0.2}Tb_{0.2}Dy_{0.2}Lu_{0.2})₃Al₅O₁₂;
(Y_{0.25}Gd_{0.25}Tb_{0.25}Lu_{0.25})₃Al₅O₁₂; (Y_{0.2}Eu_{0.2}Gd_{0.2}Yb_{0.2}Lu_{0.2})₃Al₅O₁₂;
(Y_{0.1667}Eu_{0.1667}Gd_{0.1667}Tb_{0.1667}Yb_{0.1667}Lu_{0.1667})₃Al₅O₁₂; (Y0.25Gdo.25 Tb0.25Luo.25) 3Al5012; (Y0.25Ndo.25Gdo.25Lu0.25)3AlsO12; (Y0.25Pro.25Gdo.25LU0.25)3AlsO12; and (Y0.25La0.25Gdo.25LU0.25)3Al5012.

In some embodiments, the optical material includes at least some amount of one or more activator ion. In some embodiments, 0.001≤y≤0.1 (i.e., the optical material includes 0.1% activator (i.e., 0.1 at % activator ion relative to the total amount of RE ions) to 10% activator. In some embodiments, 0.005≤y≤0.05 (e.g., 0.005, 0.006, 0.007, 0.008, 0.009, 0.010, 0.015, 0.020, 0.025, 0.030, 0.035, 0.040, 0.045, or 0.050). In some embodiments, y is 0.005, 0.02 or 0.05. In some embodiments, X is a Ce ion, a Pr ion, or a Tb ion. In some embodiments, X is a Ce ion, a Pr ion, or a mixture thereof. In some embodiments, X is Ce³⁺.

In some embodiments, the optical material comprises or consists of a composition selected from the group comprising:
(Y_{0.199}Gd_{0.199}Tb_{0.199}Yb_{0.199}Lu_{0.199}Ce_{0.005})₃Al₅O₁₂;
(Y_{0.24875}Gd_{0.24875}Er_{0.24875}Lu_{0.24875}Ce_{0.005})₃Al₅O₁₂;
(Y_{0.24875}Gd_{0.24875}Ho_{0.24875}Lu_{0.24875}Ce_{0.005})₃Al₅O₁₂;
(Y_{0.199}Gd_{0.199}Tb_{0.199}Dy_{0.199}Lu_{0.199}Ce_{0.005})₃Al₅O₁₂;
(Y_{0.24875}Gd_{0.24875}Tb_{0.24875}Lu_{0.24875}Ce_{0.005})₃Al₅O₁₂;
(Y_{0.199}Eu_{0.199}Gd_{0.199}Yb_{0.199}Lu_{0.199}Ce_{0.005})₃Al₅O₁₂;
(Y_{0.16583}Eu_{0.16583}Gd_{0.16583}Tb_{0.16583}Yb_{0.16583}Lu_{0.16583}Ce_{0.005})₃Al₅O₁₂;
(Y_{0.24875}Sm_{0.24875}Gd_{0.24875}Lu_{0.24875}Ce_{0.005})₃Al₅O₁₂;
(Y_{0.24875}Nd_{0.24875}Gd_{0.24875}Lu_{0.24875}Ce_{0.005})₃Al₅O₁₂;
(Y_{0.24875}Pr_{0.24875}Gd_{0.24875}Lu_{0.24875}Ce_{0.005})₃Al₅O₁₂;
(Y_{0.24875}La_{0.24875}Gd_{0.24875}Lu_{0.24875}Ce_{0.005})₃Al₅O₁₂;
(Y_{0.245}Gd_{0.245}Tb_{0.245}Lu_{0.245}Ce_{0.002})₃Al₅O₁₂;
(Y_{0.2375}Gd_{0.2375}Tb_{0.2375}Lu_{0.2375}Ce_{0.05})₃Al₅O₁₂;
(Y_{0.2375}Gd_{0.2375}Tb_{0.2375}Lu_{0.2375}Ce_{0.05})₃Al₅O₁₂; and
(Y_{0.294}Gd_{0.294}Tb_{0.098}Lu_{0.294}Ce_{0.02})₃Al₅O₁₂.

In some embodiments, the optical material comprises or consists of a composition selected from the group comprising:
(Y_{0.33167}Tb_{0.33167}Gd_{0.33167}Ce_{0.005})₃Al₅O₁₂;
(Lu_{0.33167}Y_{0.33167}Gd_{0.33167}Ce_{0.005})₃Al₅O₁₂;
(Lu_{0.33167}Y_{0.33167}Tb_{0.33167}Ce_{0.005})₃Al₅O₁₂;
(Lu_{0.24875}Y_{0.24875}Tb_{0.24875}Gd_{0.24875}Ce_{0.005})₃Al₅O₁₂; and
(Lu_{0.245}Y_{0.245}Tb_{0.245}Gd_{0.245}Ce_{0.002})₃Al₅O₁₂; and

In some embodiments, the optical material provides light emission from an optically active RE ion upon stimulation of the optical material with high energy radiation. In some embodiments, the optically active RE ion is a Dy ion, Er ion, Sm ion, Eu ion, Yb ion, Tb ion, or Pr ion, or any combination of any of the foregoing. In some embodiments, the optically active RE ion is a Tb ion or a Pr ion. In some embodiments, the optically active RE ion is a Tb ion. In some embodiments, the optical material includes an optically active RE ion, such as a Tb ion, as one of the RE ions and further includes another ion as an activator ion, such as, a Ce ion, a Dy ion, a Eu ion, a Yb ion, or a Pr ion. Alternatively, in some embodiments, Tb is used as an activator ion (e.g., at a relative at % compared to other RE ions of 10 atomic % or less) and the optical material includes ions of at least three other RE elements.

The optical material can be provided as a single crystal, a polycrystalline material, a powder (e.g., a green powder), or a ceramic.

### III. Radiation Detectors, Related Devices and Methods

In some embodiments, the presently disclosed subject matter provides a radiation detector comprising an optical material as described hereinabove or a mixture of such materials. For instance, the radiation detector can comprise an optical material that has the ability to act as a scintillator (which absorbs radiation and emits light) and a photodetector (which detects said emitted light). The photodetector can be any suitable detector or detectors and can be or not be optically coupled to the optical material for producing an electrical signal in response to emission of light from the optical material. Thus, the photodetector can be configured to convert photons to an electrical signal. For example, a signal amplifier can be provided to convert an output signal from a photodiode into a voltage signal. The signal amplifier can also be designed to amplify the voltage signal. Electronics associated with the photodetector can be used to shape and digitize the electronic signal.

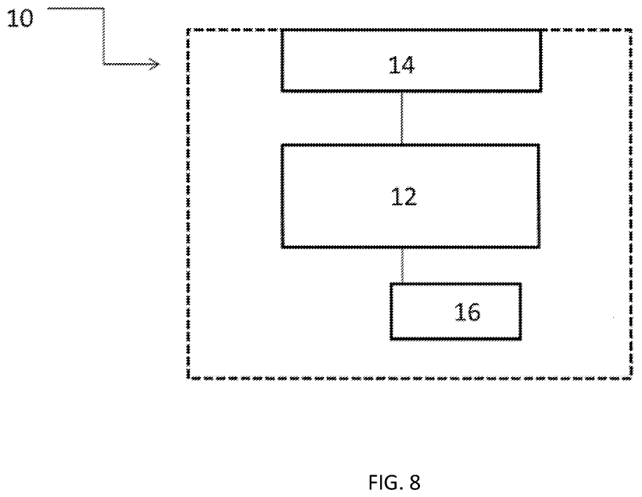

Referring now to FIG. 8, in some embodiments, the presently disclosed subject matter provides an apparatus 10 for detecting radiation wherein the apparatus comprises a photon detector 12 and a scintillator material 14 (e.g., a rare-earth garnet optical material that acts as a scintillator). Scintillator material 14 can convert radiation to light that can be collected by a charge-coupled device (CCD) or a photomultiplier tube (PMT) or other photon detector 12 efficiently and at a fast rate.

Referring again to FIG. 8, photon detector 12 can be any suitable detector or detectors and can be optically coupled (e.g., via optical grease or another optical coupling compound, such as an optical coupling oil or liquid) to the scintillator for producing an electrical signal in response to emission of light from the scintillator. Thus, photon detector 12 can be configured to convert photons to an electrical signal. Electronics associated with photon detector 12 can be used to shape and digitize the electronic signal. Suitable photon detectors 12 include, but are not limited to, photomultiplier tubes, photodiodes, CCD sensors, and image intensifiers. Apparatus 10 can also include electronics 16 for recording and/or displaying the electronic signal.

In some embodiments, the radiation detector is configured for use as part of a medical or veterinary diagnostic device, a device for oil or other geological exploration (e.g., oil well logging probes), or as a device for security and/or military-related purposes (e.g., as a device for container, vehicle, or baggage scanning or for scanning humans or other animals). In some embodiments, the medical or veterinary diagnostic device is selected from, but not limited to, a positron emission tomography (PET) device, an X-ray computed tomography (CT) device, a radiography device, a single photon emission computed tomography (SPECT) device, or a planar nuclear medical imaging device. For example, the radiation detector can be configured to move (e.g., via mechanical and/or electronic controls) over and/or around a sample, such as a human or animal subject, such that it can detect radiation emitted from any desired site or sites on the sample. In some embodiments, the detector can be set or mounted on a rotating body to rotate the detector around a sample. In some embodiments, the radiation detector is configured for use in CT, radiography, or high energy physics research.

In some embodiments, the device can also include a radiation source. For instance, an X-ray CT device of the presently disclosed subject matter can include an X-ray source for radiating X-rays and a detector for detecting said X-rays. In some embodiments, the device can comprise a plurality of radiation detectors. The plurality of radiation detectors can be arranged, for example, in a cylindrical or other desired shape, for detecting radiation emitted from various positions on the surface of a sample.

In some embodiments, the presently disclosed subject matter provides a method for detecting radiation (or the absence of radiation) using a radiation detector comprising a rare-earth garnet optical material (i.e., a scintillator material comprising a rare-earth garnet optical material) as described hereinabove. Thus, in some embodiments, the presently disclosed subject matter provides a method of detecting gamma rays, X-rays, cosmic rays and particles having an energy of 1 keV or greater, wherein the method comprises using a radiation detector comprising a rare-earth garnet optical material as disclosed herein or a mixture of such materials. In some embodiments, the method comprises using the radiation detector in computed tomography, radiography, or high energy physics research.

In some embodiments, the method can comprise providing a radiation detector comprising a photodetector and rare-earth garnet optical material of the presently disclosed subject matter; positioning the detector, wherein the positioning comprises placing the detector in a location wherein the optical material is in the path of a beam of radiation (or the suspected path of a beam of radiation); and detecting light (or detecting the absence of light) emitted by the optical material with the photodetector. Detecting the light emitted by the optical material can comprise converting photons to an electrical signal. Detecting can also comprise processing the electrical signal to shape, digitize, or amplify the signal. The method can further comprise displaying the electrical signal or processed electrical signal.

In some embodiments, the presently disclosed subject matter provides for the use of a radiation detector comprising a photon detector and a scintillator material comprising a rare-earth garnet optical material as described hereinabove. In some embodiments, the use is for medical or veterinary diagnostics (e.g., the radiation detector is configured for use in medical or veterinary diagnostics). In some embodiments, the use is in computed tomography, radiography, or high energy physics research.

### IV. Methods of Preparation of Optical Materials

The presently disclosed materials can be prepared by any suitable route, such as but not limited to a crystal synthesis route, a powder synthesis route, or a ceramic synthesis route. Representative, non-limiting examples of such routes are disclosed in the Examples below, and other examples of such routes and other synthesis routes as would be apparent to one of ordinary skill in the art upon a review of the instant disclosure also fall within the scope of the presently disclosed subject matter.

For example, in some embodiments, the appropriate reactants (e.g., metal nitrates or metal oxides, such as Lu₂O₃, CeO₂, Pr₆O₃, α-Al₂O₃, Ga₂O₃, Gd₂O₃, etc.) are melted at a temperature sufficient to form a congruent, molten composition. The melting temperature can depend on the identity of the reactants themselves (e.g., on the melting points of the individual reactants), but is usually in the range of from about 300° C. to about 1350° C. Exemplary techniques for preparing the materials include, but are not limited to, the Bridgman or Bridgman-Stockbarger method, the Czochralski method, the zone-melting method (or “floating zone” method), the vertical gradient freeze (VGF) method, and temperature gradient methods.

For instance, in some embodiments, high purity reactants can be mixed and melted to synthesize a compound of the desired composition. A single crystal or polycrystalline material can be grown from the synthesized compound by the Bridgman method, in which a sealed ampoule containing the synthesized compound is transported from a hot zone to a cold zone through a controlled temperature gradient at a controlled speed (i.e., a “pulling rate”). In some embodiments, high purity reactants can be mixed in stoichiometric ratios depending upon the desired composition of the optical material and loaded into an ampoule, which is then sealed. After sealing, the ampoule is heated and then cooled at a controlled speed. In some embodiments, an optical material (e.g., a scintillator material) of the presently disclosed subject matter is prepared via the vertical Bridgman technique. In some embodiments, the pulling (or translation) rate used in preparing scintillator crystals via the Bridgman technique is about 0.1 millimeters per hour (mm/hr) to about 5 mm/hr (e.g., about 0.1 mm/hr; about 0.5 mm/hr, about 1 mm/hr, about 2 mm/hr, about 3 mm/hr, about 4 mm/hr, or about 5 mm/hr). In some embodiments, the method comprises using a pulling rate of about 3 mm/h.

In some embodiments, the presently disclosed subject matter provides a method of preparing an optical material comprising a rare-earth garnet (RE)₃(AlGa)₅O₁₂, wherein RE is a mixture of ions of at least three rare-earth elements, optionally wherein up to about 10 atomic % of the RE ions are replaced by one or more activator ions of elements selected from Ce, Tb, Dy, Eu, Yb, and Pr. In some embodiments, the method comprises heating a mixture of raw materials (e.g., a mixture of metal oxides in a stoichiometric ratio depending upon the formula of the desired optical material) above their respective melting temperatures (i.e., above the melting temperature of the raw material with the highest melting temperature). In some embodiments, the raw materials are dried prior to, during, or after mixing. In some embodiments, the raw materials are mixed under low humidity and/or low oxygen conditions. In some embodiments, the raw materials are mixed in a dry box and/or under conditions of less than about 0.1 parts-per-million (ppm) moisture and/or oxygen (e.g., less than about 0.1 ppm, less than about 0.09 ppm, less than about 0.08 ppm, less than about 0.07 ppm, less than about 0.06 ppm, less than about 0.05 ppm, less than about 0.04 ppm, less than about 0.03 ppm, less than about 0.02 ppm, or less than about 0.01 ppm moisture and/or oxygen).

The mixture of raw materials can be sealed in a container (e.g., a quartz ampoule) that can withstand the subsequent heating of the mixture and which is chemically inert to the mixture of raw materials. The mixture can be heated at a predetermined rate to a temperature above the melting temperature of the individual raw materials. In some embodiments, the mixture can be heated to a temperature that is between about 10° C. and about 50° C. (e.g., about 10° C., about 12° C., about 14° C., about 16° C., about 18° C., about 20° C., about 22° C., about 24° C., about 26° C., about 28° C., about 30° C., about 32° C., about 34° C., about 36° C., about 38° C., about 40° C., about 42° C., about 44° C., about 46° C., about 48° C., or about 50° C.) above the melting temperature of the raw material with the highest melting temperature. In some embodiments, the mixture is heated to about 50° C. above the melting temperature of the raw material with the highest melting temperature. This temperature can be maintained for a period of time, such as between about 2 and about 36 hours (e.g., about 2, about 3, about 4, about 5, about 6, about 7, about 8, about 9, about 10, about 11, about 12, about 14, about 16, about 18, about 20, about 22, about 24, about 26, about 28, about 30, about 32, about 34, or about 36 hours). In some embodiments, the temperature is maintained for about 24 hours. Then the mixture can be cooled at a predetermined rate until the mixture reaches about room temperature (e.g., between about 20° C. and about 25° C.). If desired, the sealed container can be rotated or inverted. In some embodiments, the heating and cooling can be repeated, e.g., to provide further mixing of all of the components in the mixture. The rotating or inverting and heating/cooling steps can be repeated one or more additional times, as desired.

In some embodiments, the method further comprises a post-growth annealing step. Thus, in some embodiments, the method further comprises annealing the optical material (e.g., the crystalline optical material). The annealing can be performed, for example, in air, nitrogen, or a mixture of nitrogen and hydrogen. The annealing can be done at any suitable temperature below the melting point of the optical material, e.g., between about 100° C. and about 1600° C. (e.g., about 100° C., about 200° C., about 300° C., about 400° C., about 500° C., about 600° C., about 700° C., about 800° C., about 900° C., about 1000° C., about 1100° C., about 1200° C., about 1300° C., about 1400° C., about 1500° C., and about 1600° C.).

In some embodiments, the optical (e.g., scintillation) materials can be provided as single crystals, as a polycrystalline material, and/or as a ceramic material. In some embodiments, the material is provided as a polycrystalline material. The polycrystalline material can have analogous physical, optical and scintillation properties as a single crystal otherwise having the same chemical composition.

In some embodiments, the presently disclosed subject matter provides a method of preparing an optical material of the presently disclosed subject matter, i.e., comprising or consisting of a composition of the formula:

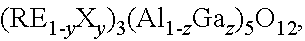

wherein: 0≤y≤0.1; 0≤z≤1; RE is a combination of ions of three or more rare-earth elements selected from the group comprising Y, Sc, Lu, Yb, Tm, Er, Ho, Dy, Tb, Gd, Eu, Sm, Nd, Pr, and La; and X is one or more activator ions selected from the group comprising a Ce ion, a Tb ion, a Dy ion, a Eu ion, a Yb ion, and a Pr ion, wherein the method comprises:
(a) preparing a single crystal of the optical material from a melt (e.g., as described above);
(b) preparing a powder of the optical material by: (i) preparing a foam by heating an aqueous solution comprising a polymer (e.g., polyvinyl alcohol (PVA) or polyethylene glycol (PEG)), and a mixture of metal nitrates, wherein the metal nitrates comprise ions of elements that correspond to elements of the optical material, and crushing said foam to provide the powder; or (ii) coprecipitating powder by adding an aqueous solution comprising a mixture of metal nitrates and ammonium sulfate to an aqueous solution of ammonium carbonate, wherein the metal nitrates comprise ions of elements that correspond to elements of the optical material; or
(c) preparing a ceramic of the optical material by a technique selected from the group comprising sintering, hot pressing, hot isotactic pressing, and spark plasma synthesis (e.g., using binary oxides as starting materials).

Thus, in some embodiments, the optical material is provided as a powder (e.g., a green body powder). In some embodiments, the powder can be prepared by preparing a foam and then crushing the foam (e.g., the dehydrated foam) to provide the powder. For example, in some embodiments, the foam can be prepared by heating an aqueous solution comprising a polymer and a mixture of metal nitrates that comprise ions of elements that correspond to the elements in the desired optical material. In some embodiments, the polymer is PVA or PEG. In some embodiments, the polymer is PVA. In some embodiments, preparing the foam further comprises heating the aqueous solution to evaporate the water from the aqueous solution. In some embodiments, the foam can be further dehydrated in an oven for a period of time to remove residual moisture. In some embodiments, the foam can be placed in an oven at about 180° C. for about 2 hours. In some embodiments, the method further comprises calcining the powder in air (e.g., at about 650° C. for about 2.5 hours) to remove nitrates and polymer (e.g., PVA). In some embodiments, the powder can be crystallized. Crystallizing can be performed in air for a period of time (e.g., about 1 hour) at a temperature of about 900° C. to about 1300° C.

Alternatively, the powder can be prepared via coprecipitation. For example, in some embodiments, the method comprises coprecipitating the powder by adding an aqueous solution comprising a mixture of metal nitrates and ammonium sulfate to an aqueous solution of ammonium carbonate, wherein the metal nitrates comprise ions of elements that correspond to elements of the optical material. The precipitate that falls outs of solution can be collected via filtration. As with the powder prepared via a foam, in some embodiments the initially precipitated powder can be calcined. In some embodiments, the powder can be crystallized (e.g., in air at a temperature of about 900° C. to about 1300° C.).

In some embodiments, a mixture of metal oxides comprising metal elements corresponding to the desired rare-earth garnet can be mixed and ground in a mortar, and then pressed into pellets.

In some embodiments, the presently disclosed subject matter provides a method of preparing a ceramic of an optical material as described herein, wherein the method comprises performing a technique selected from the group comprising hot pressing, hot isotactic pressing, and spark plasma synthesis. In some embodiments, the method comprises use of binary oxides as the starting materials for the ceramic. For instance, in some embodiments, the annealing can comprise grinding a stoichiometric mixture of binary oxides, pressing the mixture to form a pellet, and annealing the pellet at a temperature of about 1500° C. for a period of time (e.g., about 10 hours). In some embodiments, a stoichiometric mixture of binary oxide powders or a rare-earth garnet powder can be hot-pressed at a temperature of about 1000° C. to about 2000° C. at about 5 MPa to about 100 MPa for a period of time (e.g., about 2 hours).

### EXAMPLES

The following examples are included to further illustrate various embodiments of the presently disclosed subject matter. However, those of ordinary skill in the art should, in light of the present disclosure, appreciate that many changes can be made in the specific embodiments which are disclosed and still obtain a like or similar result without departing from the spirit and scope of the presently disclosed subject matter.

### Example 1

### Powder Synthesis

### Polymer Synthesis Route:

Metal nitrates were dissolved in a beaker of deionized (DI) water and polyvinyl alcohol (PVA, 9k-10k g/mol, 80% hydrolyzed) was dissolved in a different beaker of DI water. Once both solutions were dissolved, they were mixed and heated on a hotplate to evaporate the water producing a foam. The foam was placed in an oven for 2 hours at 180° C. to remove residual moisture. The powder produced by crushing the dehydrated foam was calcined at 650° C. in air for 2.5 hours to remove nitrates and PVA. The resulting powder was crystallized in air for 1 hour at temperatures varying between 900-1300° C. The result is a multi-component rare-earth garnet powder.

### Coprecipitation Route:

Metal nitrates and ammonium sulfate were dissolved in a beaker of DI water and ammonium carbonate was dissolved in a separate beaker of DI water. The nitrate solution was added dropwise into the carbonate solution forming precipitates. The precipitates were filtered out of the combined solution and calcined at 650° C. in air for 2.5 hours. The resulting powder was crystallized in air for 1 hour at temperatures varying between 900-1300° C. The result is a multi-component rare-earth garnet powder.

### Example 2

### Synthesis of Ceramics

Ceramics can be prepared from a multi-component rare-earth garnet powder prepared in Example 1 or from binary oxide powders with at least 99.99% purity that were dried at 800° C. for 5 h in air.

### Annealing:

Stoichiometric mixtures of the dried powders were ground in an agate mortar and pressed into pellets with 13 mm diameter. The pellets were sintered at 1500° C. for 10 h in air.

### Hot-Pressing:

Stoichiometric binary oxide powders or multi-component rare-earth garnet powders were pressed into pellets with 13 mm diameter. The resulting green body pellet was hot-pressed at temperatures of 1400-1500° C. at 5-10 MPa for 2 hours.

### Example 3

### Synthesis of Single Crystals

Stoichiometric mixtures of the dried powders were mixed by manual agitation in 4 ml glass vials. Cylindrical single crystals with 3 mm in diameter were grown using a KDN Dai-Ichi Kiden micro-pulling-down furnace (Dai-Ichi Kiden Co., Ltd., Tokyo, Japan) equipped with a radiofrequency (RF) generator model TR-02001 operated at 26 kilovolt-amps (kVA). A Ø16 mm iridium crucible with a Ø3 mm die and a Ø0.5 mm capillary channel was used as a melt reservoir. Growth was initiated by touching the outlet of the capillary channel with a Czochralski-grown Lu₃Al₅O₁₂ crystal seed. The RF generator power was ramped over a period of 2 hours to achieve the melting point, which was visually determined by probing the capillary with the seed and observing the presence of molten material. A charge-coupled device (CCD) camera was focused on the bottom of the crucible die to allow real time visualization of seeding and monitoring of the molten zone. The pulling rates used were in the range of 0.05-0.20 mm/min. After growth was finished, the RF generator power ramp-down was conducted over a period of four hours. The resulting single crystals had good optical quality. Discs with a thickness of 1 mm were cut and polished for optical and scintillation characterization.

### Example 4

### Characterization of Rare-Earth Garnet Optical Materials

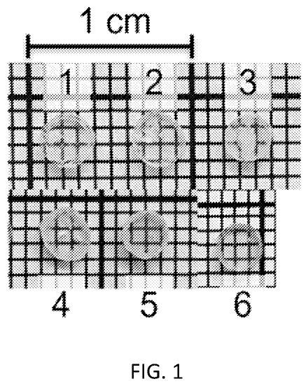

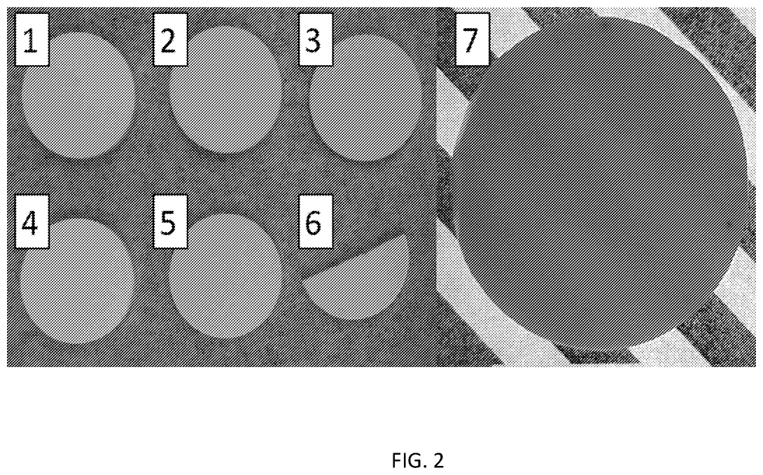

Photos of crystals, ceramics, and green bodies of materials of the presently disclosed subject matter are shown in FIGS. 1 and 2.

Specific examples of single crystals include, but are not limited to, the crystals reported in Table 1, below.

TABLE 1
Scintillations properties of multicomponent (RE₁₋ₓCeₓ)₃Al₅O₁₂

| | Light | Max |
|---|---|---|
| | output | radioluminescence |
| Composition | (ph/MeV) | (nm) |
| (Y_{1/3}Tb_{1/3}Gd_{1/3})₃Al₅O₁₂:Ce 0.5% | 7700 | 553 |
| (Lu_{1/3}Y_{1/3}Gd_{1/3})₃Al₅O₁₂:Ce 0.5% | 14800 | 564 |
| (Lu_{1/3}Y_{1/3}Tb_{1/3})₃Al₅O₁₂:Ce 0.5% | 14600 | 545 |
| (Lu_{1/4}Y_{1/4}Tb_{1/4}Gd_{1/4})₃Al₅O₁₂:Ce 0.5% | 16700 | 560 |
| (Lu_{1/4}Y_{1/4}Tb_{1/4}Gd_{1/4})₃Al₅O₁₂: Ce 2% | 13500 | 560 |

### Structural Properties

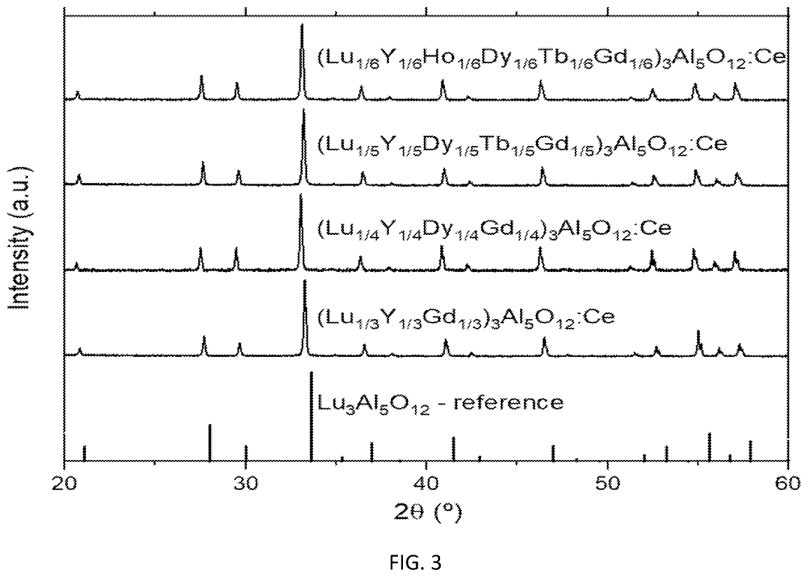

Despite the complexity of the multicomponent compositions, powder X-ray diffraction (XRD) reveals a single cubic garnet structure with a space group Ia-3d. Examples of powder XRD patterns for the (RE₁₋ₓCeₓ)₃Al₅O₁₂ crystals are presented in FIG. 3. Without being bound to any one theory, since these single crystals were grown from the melt, it is believed that the compounds melt congruently. Additionally, there is no indication of phase transitions from the crystallization temperature to room temperature.

### Optical and Scintillation Properties

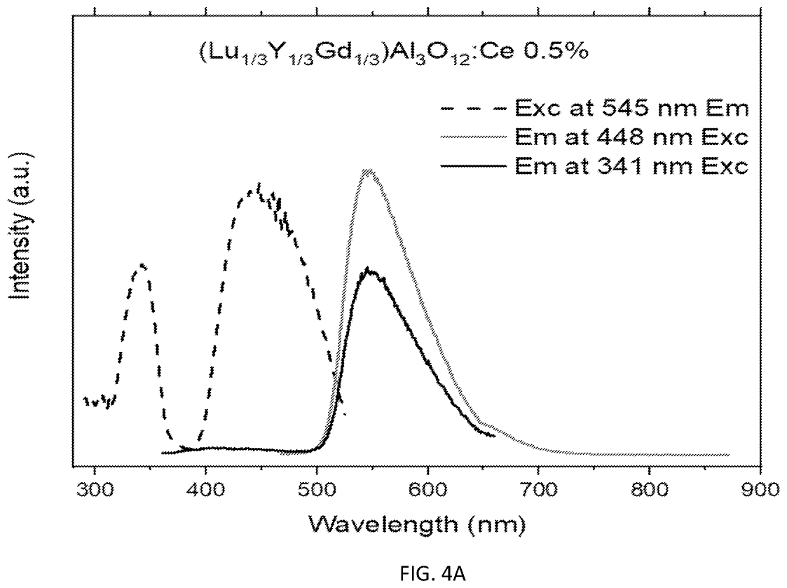

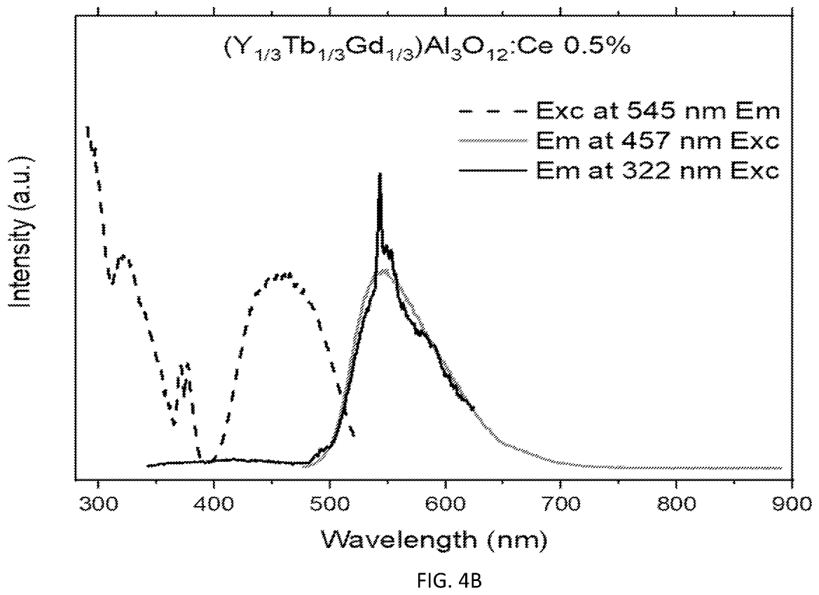

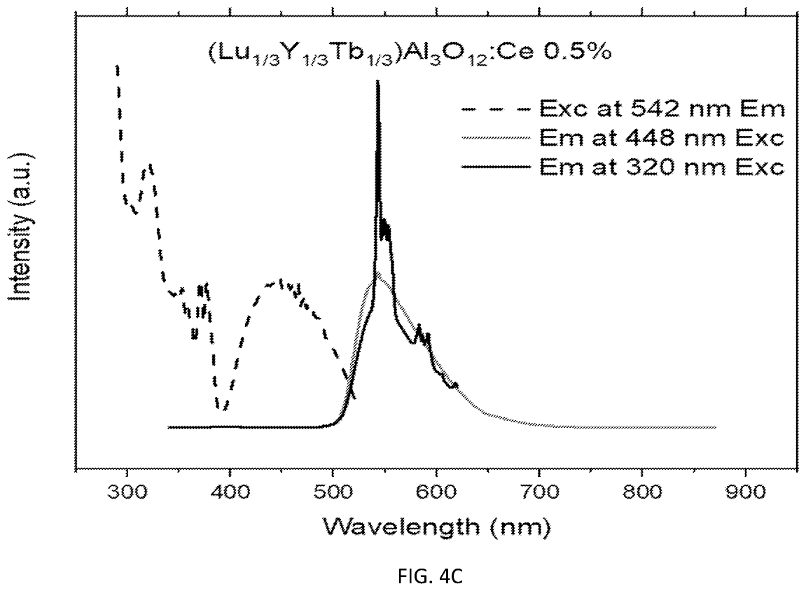

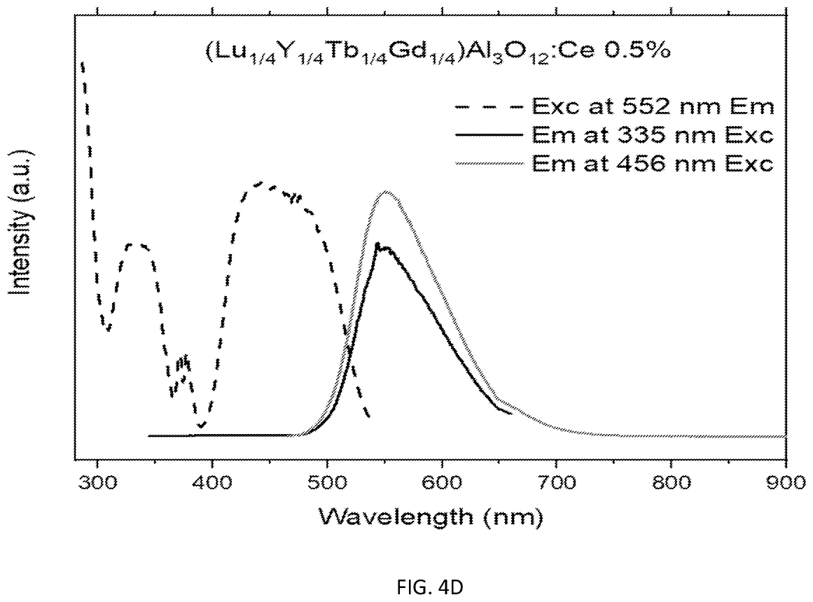

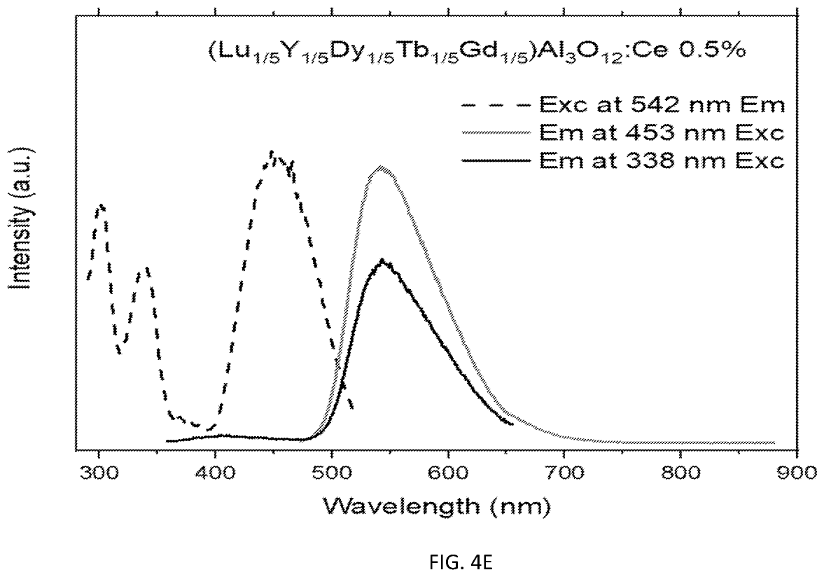

Photoluminescence (PL) spectra were acquired with a Hitachi Fluorescence Spectrophotometer (Hitachi, Tokyo, Japan) equipped with a Xenon lamp at room temperature. The spectra shown in FIGS. 4A-4E have features characteristic of trivalent Ce luminescence, which involves the 4f-5d transitions, which have also been observed in one- and two-component (RE₁₋ₓCeₓ)₃Al₅O₁₂ [2-9]. These PL spectra include Ce³⁺ emission bands with maxima in the range of 542-552 nm and excitation bands corresponding to the Ce³⁺ 4f-5d₁ and 4f-5d₂ transitions, which have maxima in the range of 448-457 nm and 335-341 nm, respectively. Additionally, the compounds containing Tb have absorption bands around 375 nm and below 300 nm, corresponding to Tb³⁺ 4f-4f transitions. In three-component compositions that contain Tb (see FIGS. 4B and 4C), the Ce³⁺ 4f-5d₂ and Tb³⁺ 4f-4f excitation bands are overlapped with maxima around 320 nm. The emission spectra monitored at these excitation maxima have the characteristic Ce³⁺ emission band overlapped with sharp Tb³⁺ 4f-4f emission peaks.

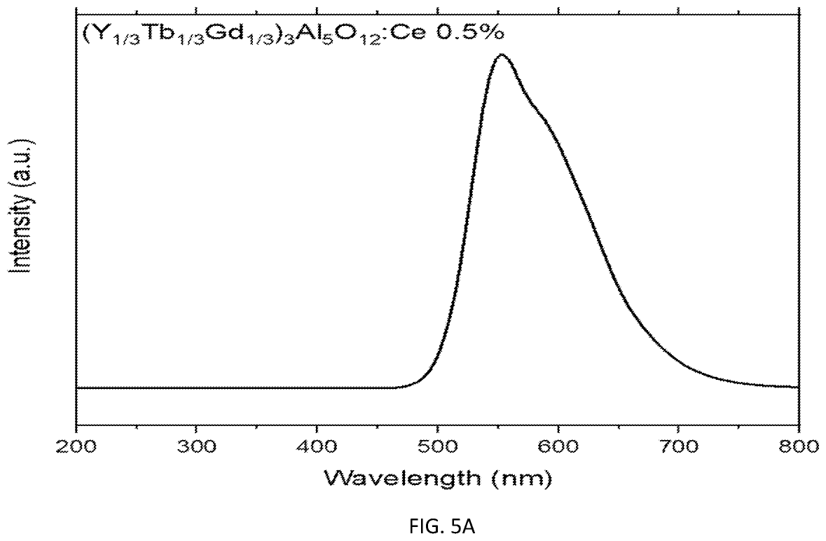

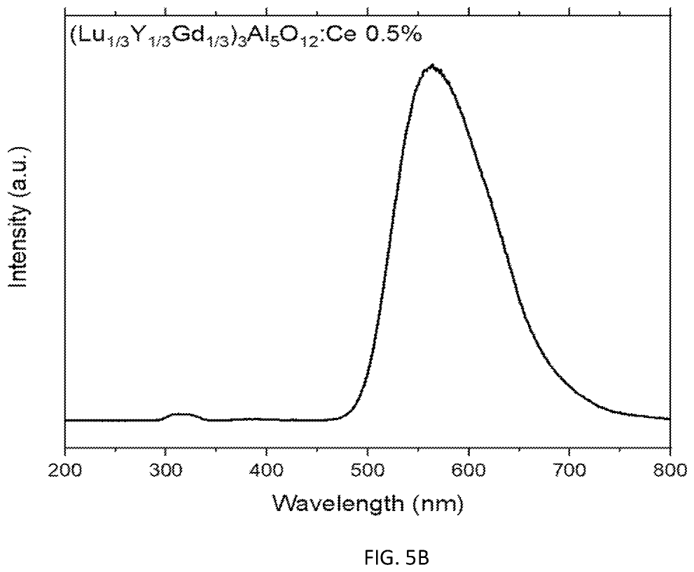

Radioluminescence (RL) spectra were measured at room temperature under continuous irradiation from a X-ray generator model CMX003 (32 kV and 0.1 mA). A monochromator sold under the tradename PI Acton SPECTRAPRO® SP-2155 (Telecyne Digital Imaging U.S. Inc., Thousand Oaks, California, United States of America) was used to record the spectra. The most intense emission bands in radioluminescence spectra shown in the FIGS. 5A-5F are Ce³⁺ emission bands with maxima in the range of 535-563 nm. The compounds containing Tb (see FIGS. 5A and 5C-5E) also have Tb³⁺ emission features around 495, 582, 625, and 652 nm.

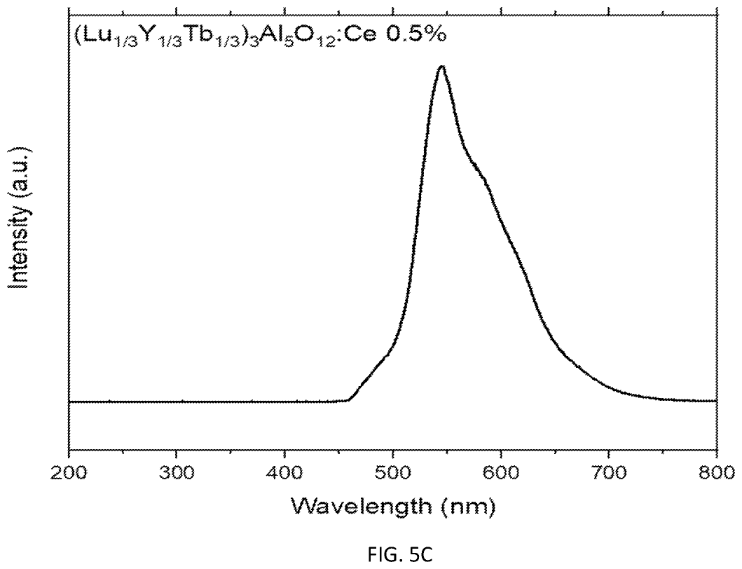

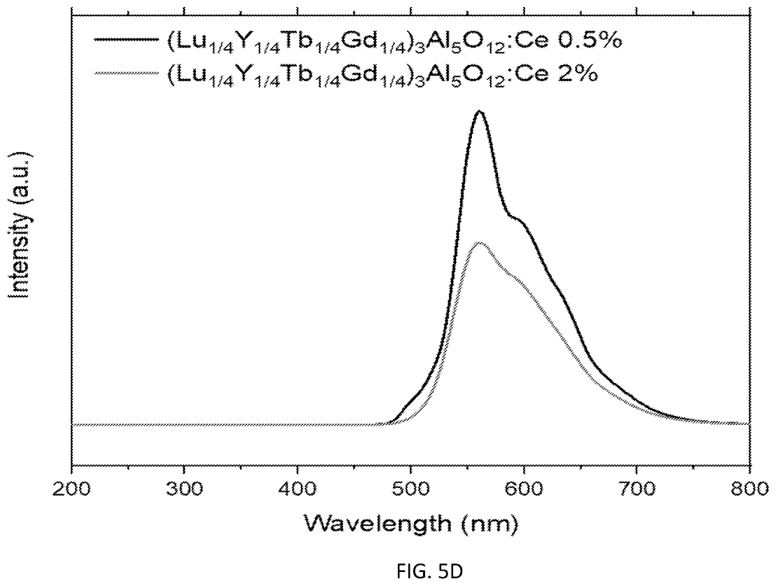

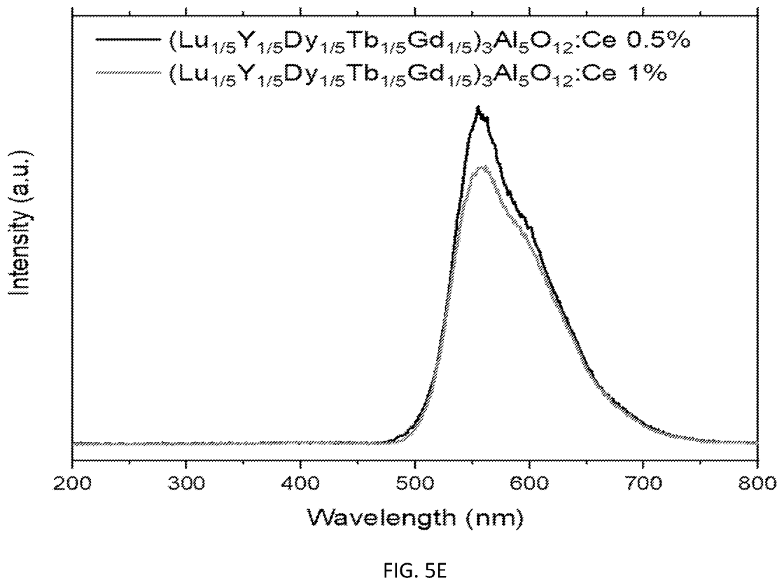

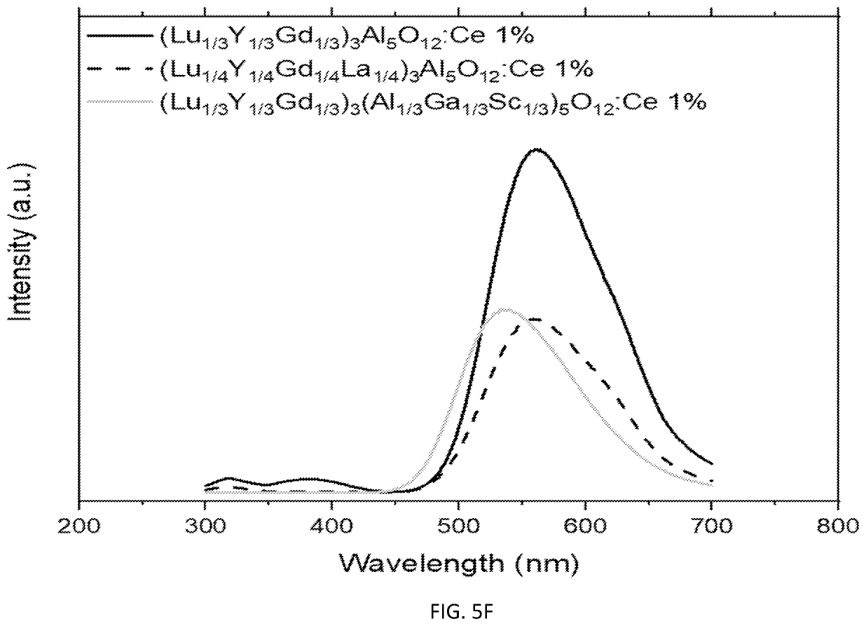

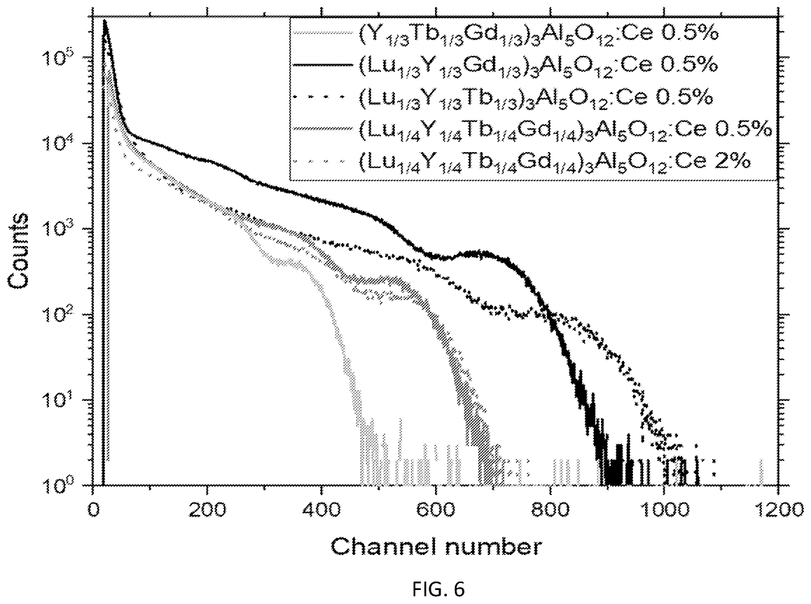

Absolute light output of the crystal samples was obtained by measuring pulse height spectra, which are presented in FIG. 6. A Hamamatsu 3177-50 photomultiplier tube (PMT) (Hamamatsu Photonics K.K., Shizuoka, Japan) was used. Samples were directly coupled to the PMT with optical grease and covered with multiple layers of polytetrafluoroethylene (PTFE) tape (sold under the tradename TEFLON®, The Chemours Company, Wilmington, Delaware, United States of America). A reflective dome prepared of polymers sold under the tradename SPECTRALON (Labsphere, Inc., North Sutton, New Hampshire, United States of America) was placed on top of the tape. Gamma-ray energy spectra were recorded using ¹³⁷Cs excitation sources. The integral quantum efficiency of PMT according to emission spectrum of the crystals was used to estimate the light output in photons per unit of gamma-ray energy, which is presented in Table 1.

### Additional Compositions

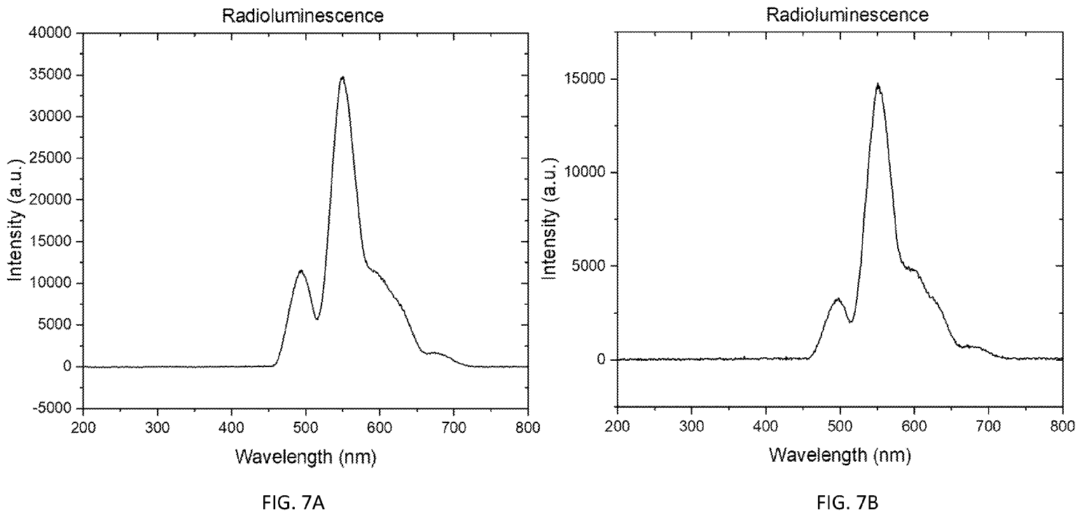

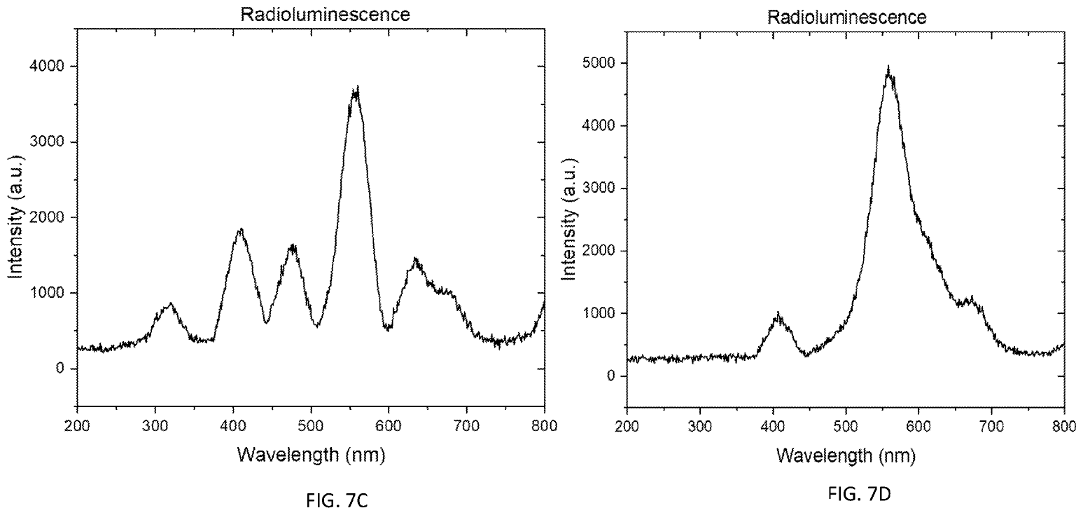

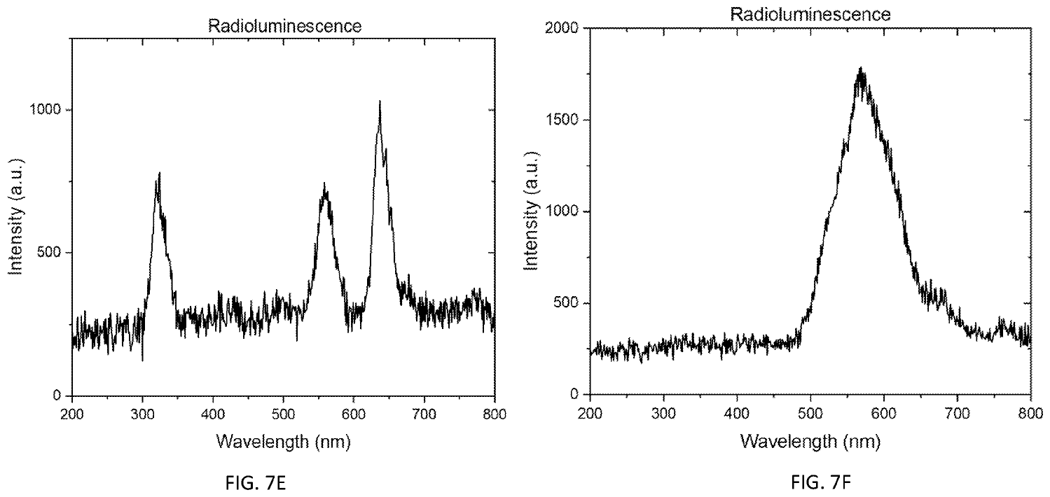

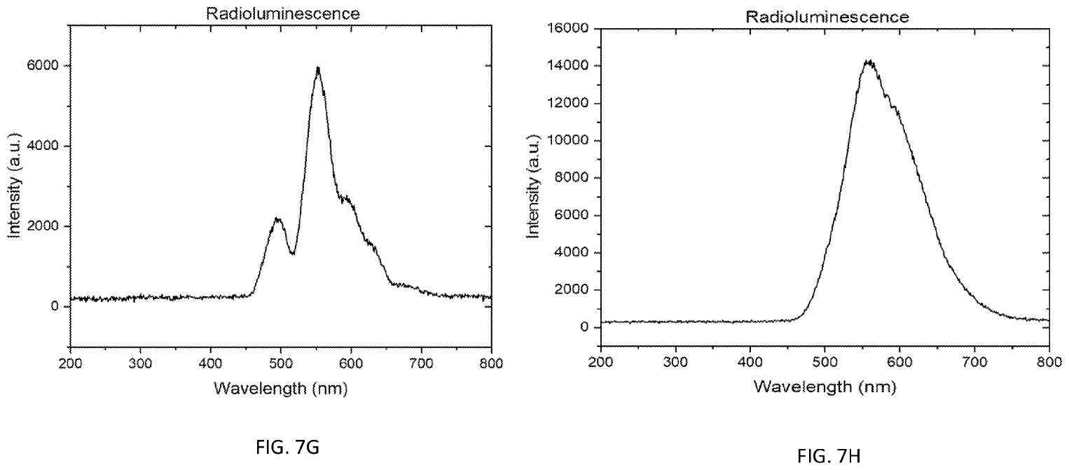

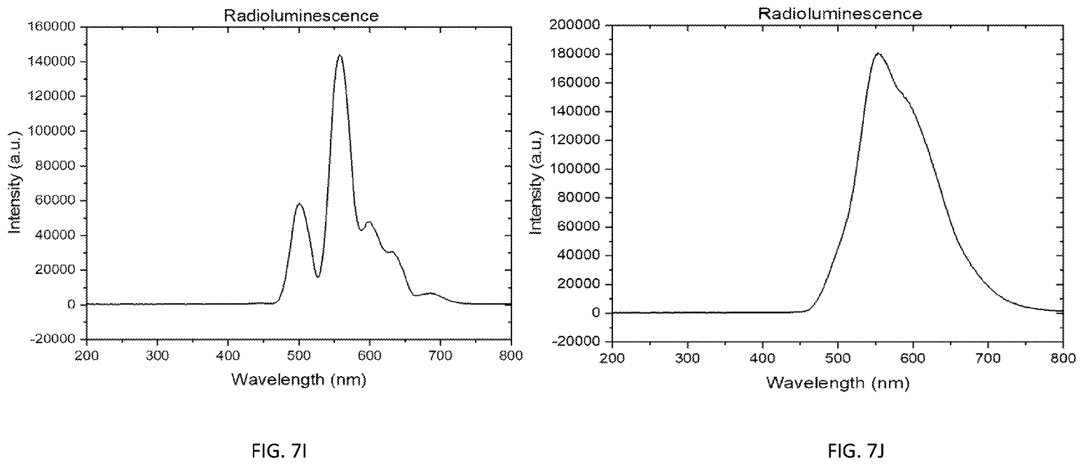

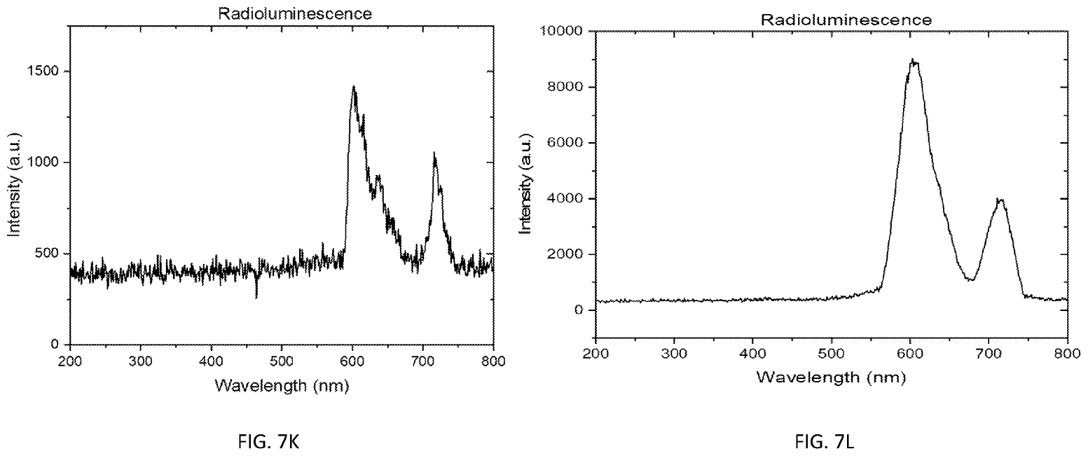

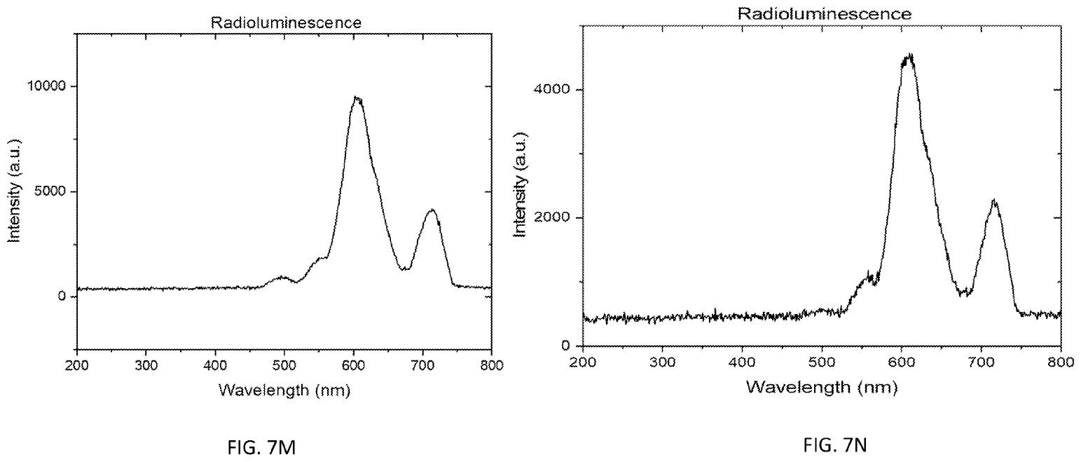

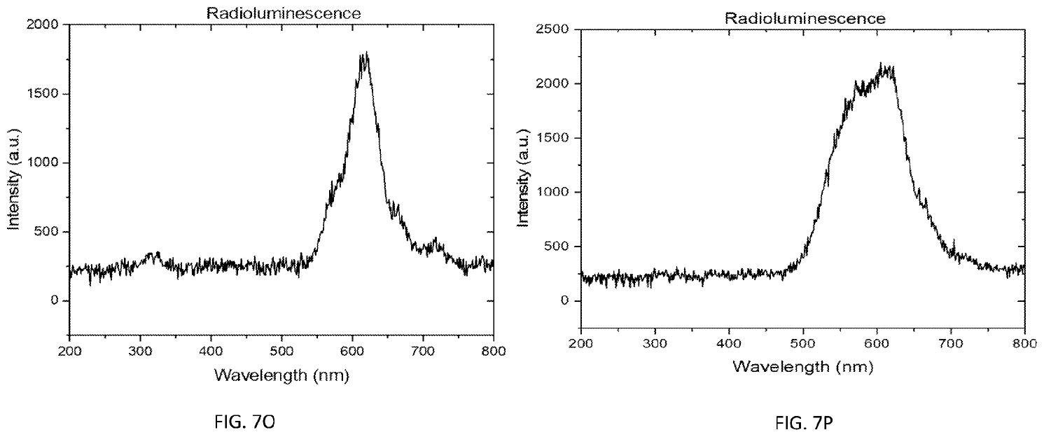

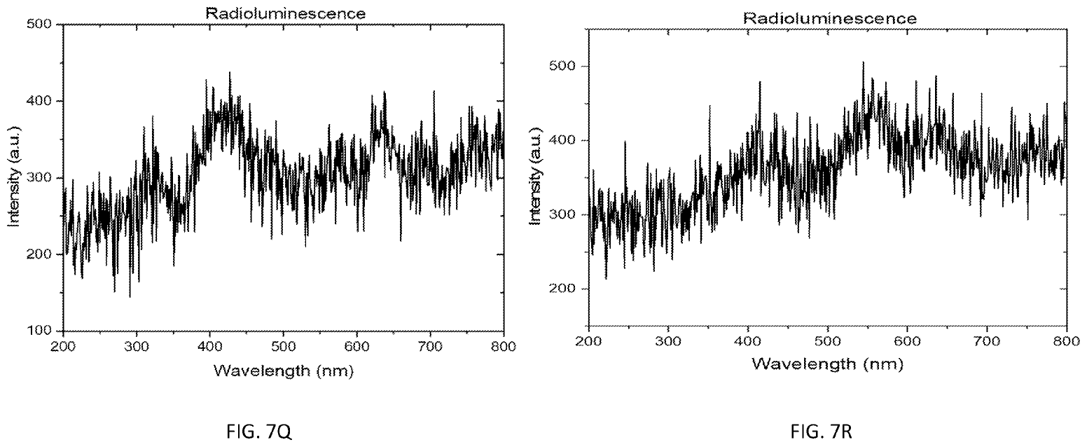

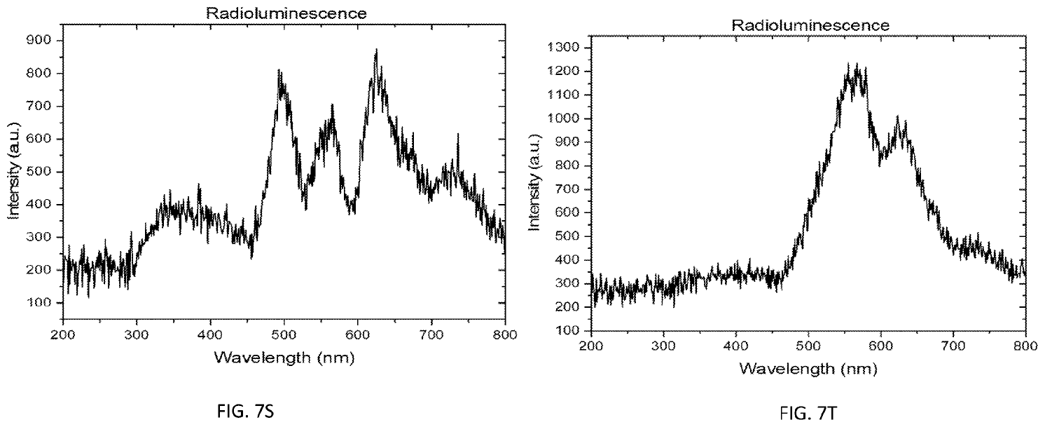

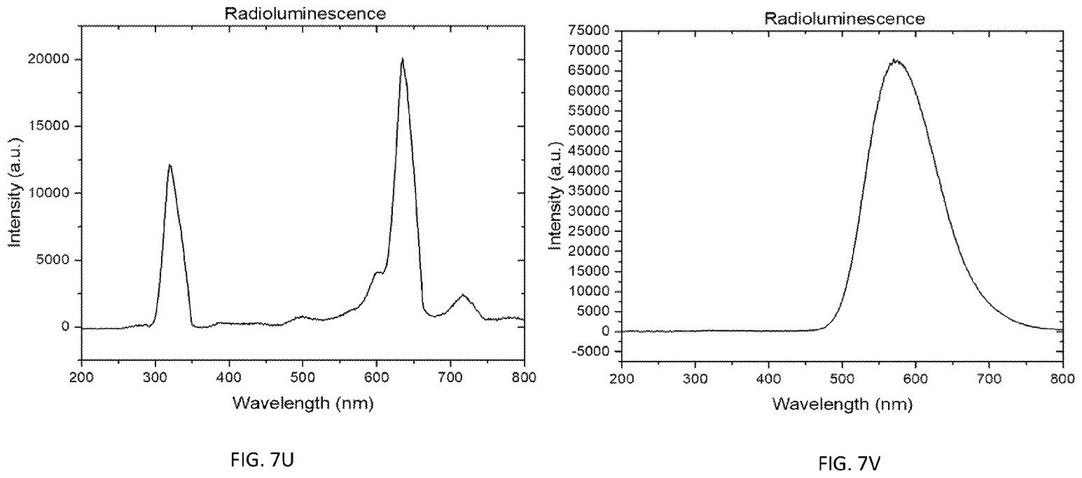

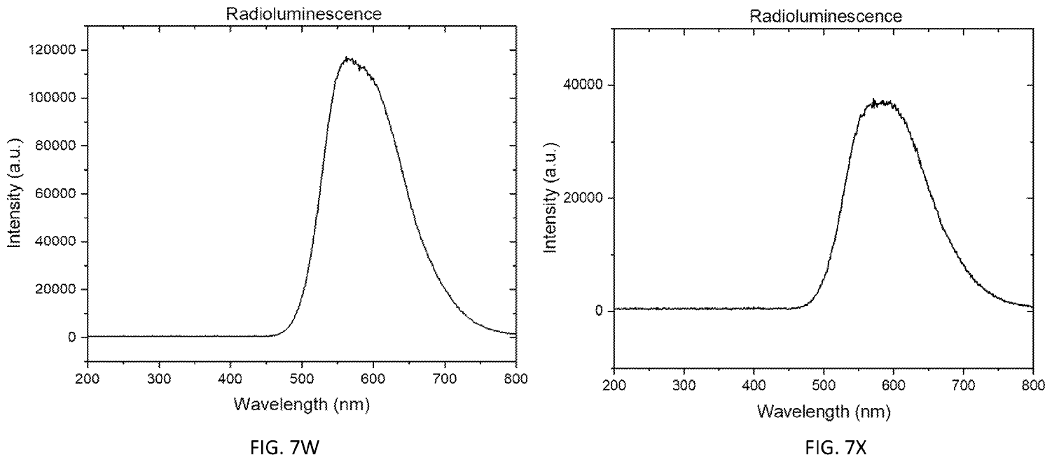

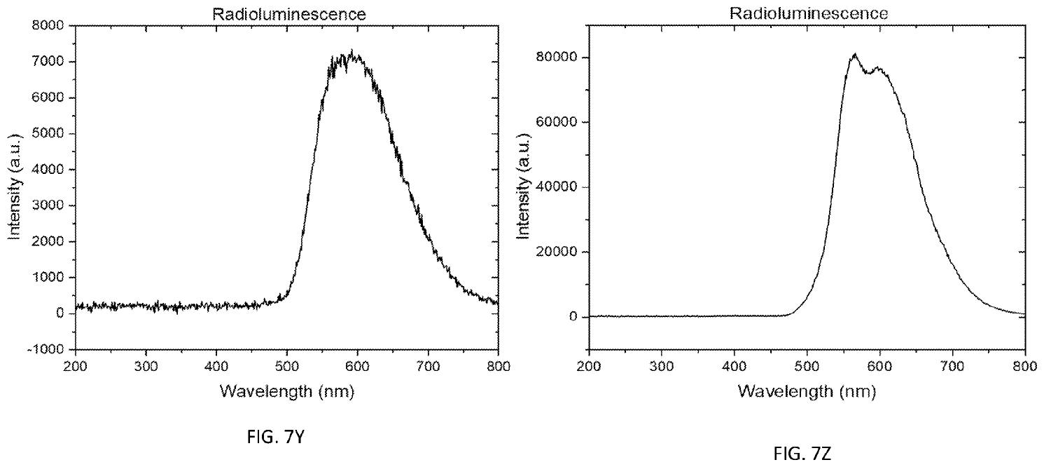

The data in Table 2 was collected from green body pellets of additional exemplary rare-earth garnets. RL spectra determined for both Ce-doped and undoped compositions exhibit scintillation emission. See FIGS. 7A-7Z. Powder XRD data presented was used to identify the formation of the garnet phase. Rietveld refinements of the powder XRD data were used to extract lattice parameters, which were then used to calculate densities of the garnet phase. The nominal composition was assumed to calculate the density, which was an appropriate assumption for phase pure samples. However, it can be noted that, for samples with secondary phases, the nominal composition could not make up the garnet phase, which can cause errors in calculating the density. Table 2, below, summarizes the RL and XRD plots for the additional exemplary rare-earth garnets.

TABLE 2
Radioluminescence and structural properties of the green body pellets.

| | Peak RL | Phase | Theoretical |
|---|---|---|---|
| | wavelength | pure | density |
| Composition | (nm) | garnet | (g/cm³) |
| (Y_{0.2}Gd_{0.2}Tb_{0.2}Yb_{0.2}Lu_{0.2})₃Al₅O₁₂ | 550 | Yes | 5.936 |
| (Y_{0.199}Gd_{0.199}Tb_{0.199}Yb_{0.199}Lu_{0.199}Ce_{0.005})₃Al₅O₁₂ | 551 | Yes | 5.940 |
| (Y_{0.25}Gd_{0.25}Er_{0.25}Lu_{0.25})₃Al₅O₁₂ | 555 | Yes | 5.867 |
| (Y_{0.24875}Gd_{0.24875}Er_{0.24875}Lu_{0.24875}Ce_{0.005})₃Al₅O₁₂ | 558 | Yes | 5.866 |
| (Y_{0.25}Gd_{0.25}Ho_{0.25}Lu_{0.25})₃Al₅O₁₂ | 320 | Yes | 5.839 |
| (Y_{0.24875}Gd_{0.24875}Ho_{0.24875}Lu_{0.24875}Ce_{0.005})₃Al₅O₁₂ | 569 | Yes | 5.840 |
| (Y_{0.2}Gd_{0.2}Tb_{0.2}Dy_{0.2}Lu_{0.2})₃Al₅O₁₂ | 554 | Yes | 5.885 |
| (Y_{0.199}Gd_{0.199}Tb_{0.199}Dy_{0.199}Lu_{0.199}Ce_{0.005})₃Al₅O₁₂ | 558 | Yes | 5.884 |
| (Y_{0.25}Gd_{0.25}Tb_{0.25}Lu_{0.25})₃Al₅O₁₂ | 557 | Yes | 5.779 |
| (Y_{0.24875}Gd_{0.24875}Tb_{0.24875}Lu_{0.24875}Ce_{0.005})₃Al₅O₁₂ | 553 | Yes | 5.775 |
| (Y_{0.2}Eu_{0.2}Gd_{0.2}Yb_{0.2}Lu_{0.2})₃A₁₅O₁₂ | 603 | Yes | 5.893 |
| (Y_{0.199}Eu_{0.199}Gd_{0.199}Yb_{0.199}Lu_{0.199}Ce_{0.005})₃Al₅O₁₂ | 606 | Yes | 5.903 |
| (Y_{0.1667}Eu_{0.1667}Gd_{0.1667}Tb_{0.1667}Yb_{0.1667}Lu_{0.1667})₃Al₅O₁₂ | 603 | Yes | 5.912 |
| (Y_{0.16583}Eu_{0.16583}Gd_{0.16583}Tb_{0.16583}Yb_{0.16583}Lu_{0.16583}Ce_{0.005})₃Al₅O₁₂ | 601 | Yes | 5.906 |
| (Y_{0.25}Sm_{0.25}Gd_{0.25}Lu_{0.25})₃Al₅O₁₂ | 618 | Yes | 5.698 |
| (Y_{0.24875}Sm_{0.24875}Gd_{0.24875}Lu_{0.24875}Ce_{0.005})₃Al₅O₁₂ | 613 | Yes | 5.700 |
| (Y_{0.25}Nd_{0.25}Gd_{0.25}Lu_{0.25})₃Al₅O₁₂ | 423 | Yes | 5.668 |
| (Y_{0.24875}Nd_{0.24875}Gd_{0.24875}Lu_{0.24875}Ce_{0.005})₃Al₅O₁₂ | 558 | Yes | 5.670 |
| (Y_{0.25}Pr_{0.25}Gd_{0.25}Lu_{0.25})₃Al₅O₁₂ | 623 | Yes | 5.602 |
| (Y_{0.24875}Pr_{0.24875}Gd_{0.24875}Lu_{0.24875}Ce_{0.005})₃Al₅O₁₂ | 571 | Yes | 5.605 |
| (Y_{0.25}La_{0.25}Gd_{0.25}Lu_{0.25})₃Al₅O₁₂ | 320 | No | 5.733 |
| (Y_{0.24875}La_{0.24875}Gd_{0.24875}Lu_{0.24875}Ce_{0.005})₃Al₅O₁₂ | 574 | No | 5.737 |
| (Y_{0.245}Gd_{0.245}Tb_{0.245}Lu_{0.245}Ce_{0.02})₃Al₅O₁₂ | 565 | Yes | 5.813 |
| (Y_{0.2375}Gd_{0.2375}Tb_{0.2375}Lu_{0.2375}Ce_{0.05})₃Al₅O₁₂ | 582 | No | 5.808 |
| (Y_{0.163}Gd_{0.163}Tb_{0.49}Lu_{0.163}Ce_{0.02})₃Al₅O₁₂ | 588 | No | 5.892 |
| (Y_{0.294}Gd_{0.294}Tb_{0.098}Lu_{0.294}Ce_{0.02})₃Al₅O₁₂ | 565 | Yes | 5.767 |

### REFERENCES

All references listed herein including but not limited to all patents, patent applications and publications thereof, scientific journal articles, and database entries are incorporated herein by reference in their entireties to the extent that they supplement, explain, provide a background for, or teach methodology, techniques, and/or compositions employed herein.
[1] Euler, F.; Bruce, J. A., Oxygen Coordinates of Compounds with Garnet Structure. Acta Crystallogr 1965, 19, 971-978.
[2] Nikl, M.; Yoshikawa, A.; Kamada, K.; Nejezchleb, K.; Stanek, C. R.; Mares, J. A.; Blazek, K., Development of LuAG-based scintillator crystals—A review. Prog Cryst Growth Ch 2013, 59 (2), 47-72.
[3] Su, X.; Zhang, K.; Liu, K.; Zhong, H.; Shi, Y.; Pan, Y., Combinatorial Optimization of (Lu1-xGdx)3Al5O12:Ce3y Yellow Phosphors as Precursors for Ceramic Scintillators. ACS Comb. Sci. 2011, 13, 79-83.
[4] Li, J.; Li, J. G.; Liu, S.; Li, X.; Sun, X.; Sakka, Y., The development of Ce3+-activated (Gd, Lu)3Al5O12 garnet solid solutions as efficient yellow-emitting phosphors. Sci. Technol. Adv. Mater. 2013 14 054201 99 pp.
[5] Hu, S.; Qin, X.; Zhou, G.; Lu, C.; Guanghui, L.; Xu, Z.; Wang, Z., Luminescence characteristics of the Ce3+-doped garnets: the case of Gd-admixed Y3Al5O12 transparent ceramics. Opt. Mater. Express 2015 5 12.
[6] Shao, C.; Zhang, L.; Zhou, T.; Gu, L.; Sun, B.; Jiang, Z.; Yao, Q.; Bu, W.; Wang, K.; Chen, H., Gd2O3 assisted densification of high quantity (Y, Gd)AG: Ce ceramic solidsolutions and their luminescence characteristics. Ceram. Int. 2018 44 8672-8678.
[7] Boukerika, A.; Guerbous, L.; Belamri, M., Effect of Y3+ substitution on structural and photoluminescence properties of solid solutions [(Lu1xYx)1z Cez]3Al5O12 phosphors. Mater. Chem. Phys. 2016 171 394-399.
[8] Yadav, S. K.; Uberuaga, B. P.; Nikl, M.; Jianng, C.; Stanek, C. R., Band-Gap and Band-Edge Engineering of Multicomponent Garnet Scintillators from First Principles. Phys. Rev. Applied. 2015 4 054012.
[9] Dorenbos, P., Electronic structure and optical properties of the lanthanide activated RE3(Al1-xGax)5O12(RE=Gd, Y, Lu) garnet compounds. Journal of Luminescence. 2013 134 310-318.

It will be understood that various details of the presently disclosed subject matter may be changed without departing from the scope of the presently disclosed subject matter. Furthermore, the foregoing description is for the purpose of illustration only, and not for the purpose of limitation.

1. An optical material comprising a composition of the formula: 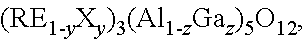
wherein:
0≤y≤0.1;
0≤z≤1;
RE is a combination of ions of three or more rare-earth elements selected from the group consisting of Y, Sc, Lu, Yb, Tm, Er, Ho, Dy, Tb, Gd, Eu, Sm, Nd, Pr, and La; and
X is one or more activator ions selected from the group consisting of a Ce ion, a Tb ion, a Dy ion, a Eu ion, an Yb ion, and a Pr ion.

2. The optical material of claim 1, wherein z is 0.

3. The optical material of claim 1, wherein RE is a combination of ions of three, four, five or six elements selected from the group consisting of Y, Sc, Lu, Yb, Tm, Er, Ho, Dy, Tb, Gd, Eu, Sm, Nd, Pr, and La.

4. The optical material of claim 1, wherein RE is a combination of ions of at least three elements selected from the group consisting of Y, Lu, Tb, and Gd.

5. The optical material of claim 1, wherein y is 0.

6. The optical material of claim 1, wherein 0.001≤y≤0.1.

7. The optical material of claim 6, wherein 0.005≤y≤0.05; optionally wherein y is 0.005, 0.02, or 0.05.

8. The optical material of claim 6 wherein X is a Ce ion, a Pr ion, or a mixture thereof, optionally wherein X is Ce³⁺.

9. The optical material of claim 1, wherein the optical material comprises a composition selected from the group consisting of:
(Y_{0.2}Gd_{0.2}Tb_{0.2}Y_{0.2}Lu_{0.2})₃Al₅O₁₂;
(Y_{0.25}Gd_{0.25}Er_{0.25}Lu_{0.25})₃Al₅O₁₂;
(Y_{0.25}Gd_{0.25}Ho_{0.25}Lu_{0.25})₃Al₅O₁₂;
(Y_{0.2}Gd_{0.2}Tb_{0.2}Dy_{0.2}Lu_{0.2})₃Al₅O₁₂;
(Y_{0.25}Gd_{0.25}Tb_{0.25}Lu_{0.25})₃Al₅O₁₂;
(Y_{0.2}Eu_{0.2}Gd_{0.2}Yb_{0.2}Lu_{0.2})₃Al₅O₁₂;
(Y_{0.1667}Eu_{0.1667}Gd_{0.1667}Tb_{0.1667}Yb_{0.1667}Lu_{0.1667})₃Al₅O₁₂;
(Y_{0.25}Gd_{0.25}Tb_{0.25}Lu_{0.25})₃Al₅O₁₂;
(Y_{0.25}Nd_{0.25}Gd_{0.25}Lu_{0.25})₃Al₅O₁₂;
(Y_{0.25}Pr_{0.25}Gd_{0.25}Lu_{0.25})₃Al₅O₁₂; and
(Y_{0.25}La_{0.25}Gd_{0.25}Lu_{0.25})₃Al₅O₁₂.

10. The optical material of claim 1, wherein the optical material comprises a composition selected from the group consisting of:
(Y_{0.199}Gd_{0.199}Tb_{0.199}Yb_{0.199}Lu_{0.199}Ce_{0.005})₃Al₅O₁₂;
(Y_{0.24875}Gd_{0.24875}Er_{0.24875}Lu_{0.24875}Ce_{0.005})₃Al₅O₁₂;
(Y_{0.24875}Gd_{0.24875}Ho_{0.24875}Lu_{0.24875}Ce_{0.005})₃Al₅O₁₂;
(Y_{0.199}Gd_{0.199}Tb_{0.199}Dy_{0.199}Lu_{0.199}Ce_{0.005})₃Al₅O₁₂;
(Y_{0.24875}Gd_{0.24875}Tb_{0.24875}Lu_{0.24875}Ce_{0.005})₃Al₅O₁₂;
(Y_{0.199}Eu_{0.199}Gd_{0.199}Yb_{0.199}Lu_{0.199}Ce_{0.005})₃Al₅O₁₂;
(Y_{0.16583}Eu_{0.16583}Gd_{0.16583}Tb_{0.16583}Yb_{0.16583}Lu_{0.16583}Ce_{0.005})₃Al₅O₁₂;
(Y_{0.24875}Sm_{0.24875}Gd_{0.24875}Lu_{0.24875}Ce_{0.005})₃Al₅O₁₂;
(Y_{0.24875}Nd_{0.24875}Gd_{0.24875}Lu_{0.24875}Ce_{0.005})₃Al₅O₁₂;
(Y_{0.24875}Pr_{0.24875}Gd_{0.24875}Lu_{0.24875}Ce_{0.005})₃Al₅O¹²;
(Y_{0.24875}La_{0.24875}Gd_{0.24875}Lu_{0.24875}Ce_{0.005})₃Al₅O¹²;
(Y_{0.245}Gd_{0.245}Tb_{0.245}Lu_{0.24875}Ce_{0.005})₃Al₅O¹²;
(Y_{0.2375}Gd_{0.2375}Tb_{0.2375}Lu_{0.2375}Ce_{0.005})₃Al₅O¹²;
(Y_{0.2375}Gd_{0.2375}Tb_{0.2375}Lu_{0.2375}Ce_{0.005})₃Al₅O¹²; and
(Y_{0.294}Gd_{0.294}Tb_{0.098}Lu_{0.294}Ce_{0.02})₃Al₅O₁₂.

11. The optical material of claim 1, wherein the optical material comprises a composition selected from the group consisting of:
(Y_{0.33167}Tb_{0.33167}Gd_{0.33167}Ce_{0.005})₃Al₅O₁₂;
(Lu_{0.33167}Yo_{0.33167}Gd_{0.33167}Ce_{0.005})₃Al₅O₁₂;
(Lu_{0.33167}Yo_{0.33167}Tb_{0.33167}Ce_{0.005})₃Al₅O₁₂;
(Lu_{0.24875}Yo_{0.24875}Tb_{0.24875}Ce_{0.005})₃Al₅O₁₂; and
(Lu_{0.245}Yo_{0.245}Tb_{0.245}Ce_{0.002})₃Al₅O₁₂; and

12. An optical material of claim 1, wherein the optical material provides light emission from an optically active RE ion upon stimulation of the optical material with high energy radiation, optionally wherein said optically active RE ion is a Tb ion.

13. A radiation detector comprising an optical material of claim 1 and a photon detector, optionally wherein the optical material is an optical material selected from the group consisting of:
(Y_{0.33167}Tb_{0.33167}Gd_{0.33167}Ce_{0.005})₃Al₅O₁₂;
(Lu_{0.33167}Yo_{0.33167}Gd_{0.33167}Ce_{0.005})₃Al₅O₁₂;
(Lu_{0.33167}Yo_{0.33167}Tb_{0.33167}Ce_{0.005})₃Al₅O₁₂;
(Lu_{0.24875}Yo_{0.24875}Tb_{0.24875}Ce_{0.005})₃Al₅O₁₂; and
(Lu_{0.245}Y_{0.245}Tb_{0.245}Gd_{0.245}Ce_{0.02})₃Al₅O₁₂.

14. A method of detecting gamma rays, X-rays, cosmic rays, and/or particles having an energy of 1 keV or greater, the method comprising using the radiation detector of claim 13.

15. Use of a radiation detector of claim 13 in medical imaging, homeland security, or high energy physics research.

16. A method of preparing an optical material of claim 1, wherein the method comprises preparing a single crystal of the optical material from a melt.

17. A method of preparing an optical material of claim 1, wherein the method comprises preparing a powder of the optical material by:
(i) preparing a foam by heating an aqueous solution comprising a polymer, optionally polyvinyl alcohol (PVA) or polyethylene glycol (PEG), and a mixture of metal nitrates, wherein the metal nitrates comprise ions of elements that correspond to elements of the optical material, and crushing said foam to provide the powder; or
(ii) coprecipitating powder by adding an aqueous solution comprising a mixture of metal nitrates and ammonium sulfate to an aqueous solution of ammonium carbonate, wherein the metal nitrates comprise ions of elements that correspond to elements of the optical material.

18. A method of preparing an optical material of claim 1, wherein the method comprises preparing a ceramic of the optical material by a technique selected from the group consisting of sintering, hot pressing, hot isotactic pressing, and spark plasma synthesis, optionally using binary oxides as starting materials.
